(19) United States
(12) Patent Application Publication
(10) Pub. No.: US 2026/0231427 A1
(43) Pub. Date: Aug. 6, 2026

(54) MEMORY DEVICE AND SEMICONDUCTOR DEVICE

(71) Applicant: Kioxia Corporation, Tokyo (JP)

(72) Inventor: Shuto YAMASAKA, Yokkaichi Mie (JP)

(21) Appl. No.: 19/326,433

(22) Filed: Sep. 11, 2025

(30) Foreign Application Priority Data
Feb. 3, 2025 (JP) 2025-016378

(51) Int. Cl. H10B 43/40; H01L 23/00; H01L 25/065; H01L 25/18; H10B 80/00

(52) U.S. Cl. CPC H10B 43/40; H10B 80/00; H10W 90/00; H10W 90/792

(57) ABSTRACT

According to one embodiment, a device includes a transistor with source/drain layers in a substrate, a gate insulation layer on the substrate, a first gate electrode on the gate insulation layer above a channel region between the source/drain layers, and a second gate electrode on the gate insulation layer above one of the source/drain layers. The second gate electrode is adjacent to the first gate electrode across a first slit and has a first opening therein reaching the source/drain layer. A first insulating layer comprising silicon nitride is in the first slit. The gate insulation layer has a first portion between the first gate electrode and the substrate and a second portion under the first slit. The first and second portions each have the same film thickness.

### CROSS-REFERENCE TO RELATED APPLICATION

This application is based upon and claims the benefit of priority from Japanese Patent Application No. 2025-016378, filed Feb. 3, 2025, the entire contents of which are incorporated herein by reference.

### FIELD

Embodiments described herein relate generally to a memory device and a semiconductor device.

### BACKGROUND

A NAND flash memory is a memory device capable of storing data in a non-volatile manner.

### BRIEF DESCRIPTION OF THE DRAWINGS

FIG. 1 is a block diagram showing an example configuration of a first memory device.

FIG. 2 is a circuit diagram of a memory cell array of the first memory device.

FIG. 3 is a circuit diagram of a row control circuit of the first memory device.

FIG. 4 is a circuit diagram of a block decoder of the first memory device.

FIG. 5 is a cross-sectional view showing an example structure of the first memory device.

FIG. 6 is a cross-sectional view showing an example structure of a memory pillar of a memory device according to a first embodiment.

FIG. 7 is a plan view showing an example structure of a transistor of a memory device according to a first embodiment.

FIG. 8 is a cross-sectional view showing an example structure of a transistor of a memory device according to a first embodiment.

FIG. 9 is another cross-sectional view showing an example structure of a transistor of a memory device according to the first embodiment.

FIG. 10 is another cross-sectional view showing an example structure of a transistor of a memory device according to a first embodiment.

FIGS. 11 to 16 depict aspects of a manufacturing method of the memory device according to a first embodiment.

FIG. 17 is a cross-sectional view showing an example structure of a transistor of a second memory device.

FIGS. 18 to 21 depict aspects of a manufacturing method of a memory device according to a second embodiment.

FIG. 22 is a cross-sectional view showing an example structure of a transistor of a memory device according to a third embodiment.

FIGS. 23 and 24 depict aspects of a manufacturing method of a memory device according to a third embodiment.

### DETAILED DESCRIPTION

Embodiments provide memory devices and the like with improved reliability.

In general, according to one embodiment, a memory device includes a memory cell, that stores data, and a first transistor. The first transistor has a first source/drain layer in a semiconductor substrate and a second source/drain layer in the semiconductor substrate and spaced from the first source/drain layer in a first direction parallel to a surface of the semiconductor substrate. A first gate insulation layer is on the semiconductor substrate. A first gate electrode is above a channel region between the first and second source/drain layers via the first gate insulation layer. A second gate electrode is above the first source/drain layer via the first gate insulation layer. The second gate electrode is adjacent to the first gate electrode across a first slit and includes therein a first opening reaching the first source/drain layer. A first insulating layer is in the first slit. The first insulating layer comprises silicon nitride. The first gate insulation layer on the semiconductor substrate includes a first portion that is between the first gate electrode and the semiconductor substrate in a second direction orthogonal to the surface of the semiconductor substrate and a second portion that is aligned with the first slit along the second direction. The first and second portions of the first gate insulation layer are the same film thickness along the second direction.

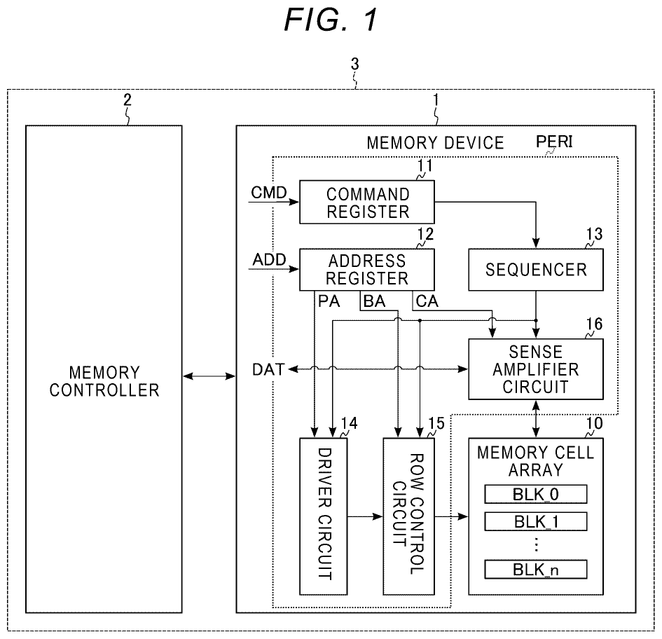

A memory device, a semiconductor device, and a manufacturing method of a memory device (and a semiconductor device) according to certain example embodiments will be described below with reference to FIGS. 1 to 24.

In the following description, components having the same functions and configurations are denoted by the same reference numerals. In addition, in the following, when components (e.g., circuits, wiring, various voltages and signals, and the like) having base reference numerals with appended suffixes (added numbers/alphabetic characters) for differentiation between different instances of the same base type component do not need to be distinguished from each other, the base notation (reference numeral) without the suffixes may be used for all instances of such components of the same base type.

### EMBODIMENTS

### (1) First Embodiment

A memory device, a semiconductor device, and a manufacturing method of the memory device (and the semiconductor device) according to a first embodiment will be described below with reference to FIGS. 1 to 16.

### (a) Example Configuration

An example configuration of the memory device according to the first embodiment will be described below with reference to FIGS. 1 to 10.

### (a-1) Circuit Configuration

FIG. 1 is a block diagram illustrating an example configuration of a memory device according to the first embodiment.

A memory system 3 includes a memory device 1 and a memory controller 2.

The memory system 3 is, for example, a memory card such as an SD™ card, a Universal serial bus (USB) device, a universal flash storage (UFS) device, and a solid state drive (SSD). The memory system 3 is configured to be connected to an external host device or the like.

The memory controller 2 can be, for example, an integrated circuit such as a system-on-a-chip (SoC). The memory controller 2 controls the memory device 1 based on a request from the host device. Specifically, the memory controller 2 writes data requested to be written by the host device to the memory device 1. The memory controller 2 reads data requested to be read by the host device from the memory device 1 and transmits the read data to the host device.

The memory device 1 is, for example, a NAND flash memory. The memory device 1 stores data in a non-volatile manner. The memory device 1 is connected to the memory controller 2 via a NAND bus.

The NAND bus is, for example, a bus conforming to a single data rate (SDR) interface, a toggle double data rate (DDR) interface, or an Open NAND flash interface (ONFI).

The memory device 1 includes a memory cell array 10 and a peripheral circuit PERI (also known as a CMOS circuit in some examples). The peripheral circuit PERI includes a command register 11, an address register 12, a sequencer 13, a driver circuit 14, a row control circuit 15, and a sense amplifier circuit 16.

The memory cell array 10 includes a plurality of blocks BLK0 to BLKn (where, n is an integer equal to or greater than 1). The block BLK is a set of a plurality of memory cells capable of storing data in a non-volatile manner. The block BLK is used, for example, as a unit of data erasure. The memory cell array 10 includes a plurality of bit lines and a plurality of word lines. Each memory cell is associated with one bit line and one word line, for example.

The command register 11 stores a command CMD that the memory device 1 receives from the memory controller 2. For example, the command CMD includes instructions for causing the sequencer 13 to execute a read operation, a write operation, an erase operation, or the like.

The address register 12 stores an address ADD that the memory device 1 receives from the memory controller 2. The address ADD includes, for example, a page address PA (e.g., word line address), a block address BA, and a column address CA. For example, the page address PA, the block address BA, and the column address CA are used for selecting a particular word line, a particular block BLK, and a particular bit line, respectively.

The sequencer 13 controls the overall operation of the memory device 1. For example, the sequencer 13 controls the driver circuit 14, the row control circuit 15, the sense amplifier circuit 16 and the like based on the command CMD stored in the command register 11. Accordingly, the sequencer 13 executes a read operation, a write operation, an erase operation, and the like.

The driver circuit 14 generates various voltages used during the read operation, the write operation, the erase operation, and the like. The driver circuit 14 applies the generated voltage to a signal line corresponding to the word line selected based on the page address PA.

The row control circuit 15 selects a block BLK in the corresponding memory cell array 10 based on the block address BA. The row control circuit 15 transfers, for example, the voltage applied to the signal line corresponding to the selected word line to the selected word line in the selected block BLK.

The sense amplifier circuit 16 transfers data DAT between the memory controller 2 and the memory cell array 10. The data DAT includes data written to the memory cell array 10 (hereinafter referred to as write data) and data read from the memory cell array 10 (hereinafter referred to as read data). More specifically, during the write operation, the sense amplifier circuit 16 transfers the write data received from the memory controller 2 to the memory cell array 10. During the read operation, the sense amplifier circuit 16 executes a determination (identification) of the data stored in the memory cell based on the presence or absence of current generation in the bit line or the voltage of the bit line. The sense amplifier circuit 16 transfers the read cell data to the memory controller 2 as the read data.

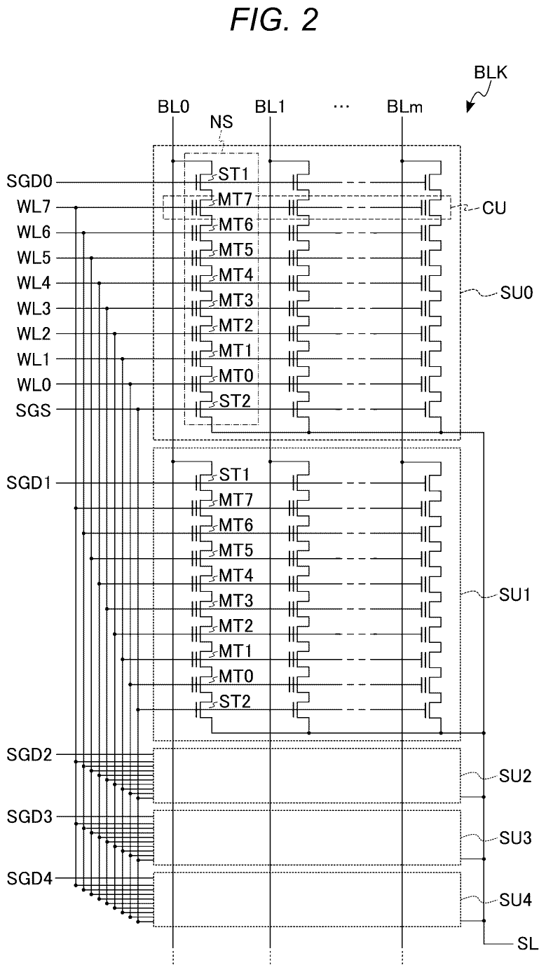

FIG. 2 is a circuit diagram showing an example of a circuit configuration of a memory cell array in the memory device 1. FIG. 2 shows one block BLK out of the plurality of blocks BLK in the memory cell array 10. In the example shown in FIG. 2, the block BLK includes, for example, five string units SU0, SU1, SU2, SU3, and SU4.

Each string unit SU includes a plurality of NAND strings NS respectively associated with bit lines BL0 to BLm (where, m is an integer equal to or greater than 1). Each NAND string NS includes, for example, a plurality of memory cells MT (e.g., MT0 to MT7) and a plurality of select transistors ST1 and ST2.

Each memory cell MT stores data in a non-volatile manner. The memory cell MT is a field effect transistor including a control gate and a charge storage layer. Hereinafter, the memory cell MT is also referred to as the memory cell transistor MT.

Each of the select transistors ST1 and ST2 is used for selecting a string unit SU during various operations.

In each NAND string NS, a plurality of memory cells MT0 to MT7 are connected in series. One end of the select transistor ST1 is connected to the associated bit line BL. The other end of the select transistor ST1 is connected to one ends of memory cells MT0 to MT7 connected in series. One end of the select transistor ST2 is connected to the other ends of the memory cells MT0 to MT7 connected in series. The other end of the select transistor ST2 is connected to a source line SL.

In the same block BLK, a control gate of each memory cell MT0 to MT7 is connected to one corresponding word line among a plurality of word lines WL0 to WL7. Each of gates of select transistors ST1 in the string units SU0 to SU4 is connected to one corresponding select gate line among a plurality of select gate lines SGD0 to SGD4. The gates of the select transistors ST2 are connected in common to a select gate line SGS. However, embodiments are not limited thereto, and each of the gates of the select transistors ST2 may be connected to different select gate lines SGS for each string unit SU.

When the word lines WL0 to WL7 are not distinguished in the following description, these are simply referred to as the word lines WL. When the select gate lines SGD0 to SGD4 are not distinguished, these are simply referred to as the select gate lines SGD.

Each of the bit lines BL0 to BLm is connected to one NAND string NS in each string unit SU across a plurality of blocks BLK. Each of the word lines WL0 to WL7 is provided on block BLK basis. For example, the source line SL is shared by a plurality of blocks BLK.

A set (group) of memory cells MT connected to a common word line WL in one string unit SU is referred to as a cell unit CU. For example, when each memory cell MT stores 1 bit of data, the size of the data stored by a cell unit CU of such memory cells MT is defined as one page (one page unit). A cell unit CU may store two or more pages of data according to the number of bits of the data stored in each memory cell MT.

The circuit configuration of the memory cell array 10 provided in the memory device 1 is not limited to the configuration described above. For example, the number of string units SU in each block BLK may be designed to be any number. Likewise, the number of memory cells MT in each NAND string NS and the number of select transistors ST1 and ST2 may be set to be any number.

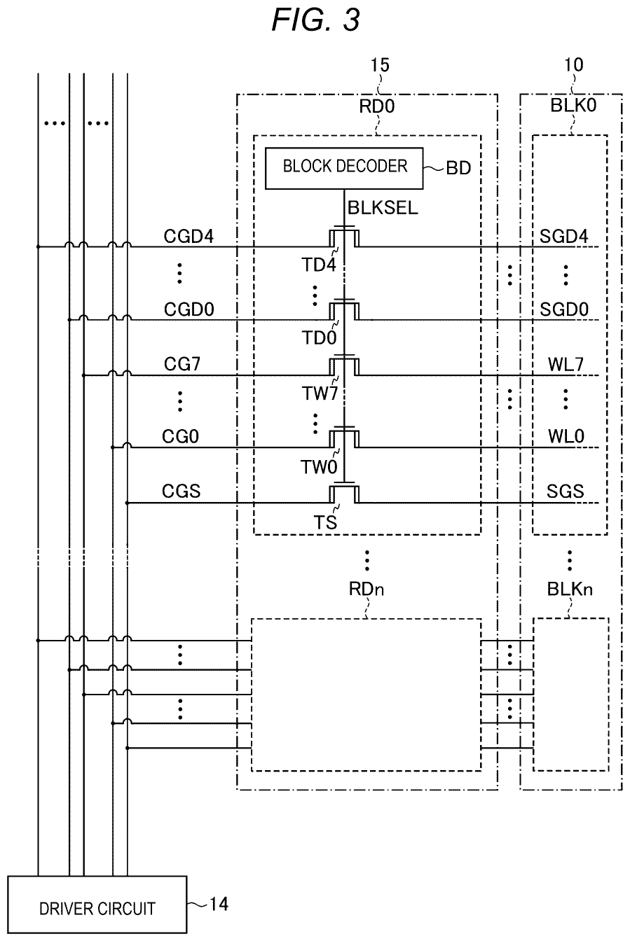

FIG. 3 is a circuit diagram illustrating an example of a configuration of the row control circuit 15, the driver circuit 14, and the memory cell array 10 in the memory device 1.

The row control circuit 15 includes a plurality of row decoders RD (e.g., RD0 to RDn). The row decoders RD0 to RDn are used for selecting the block BLK. The row decoders RD0 to RDn are respectively associated with the blocks BLK0 to BLKn.

Each of the row decoders RD includes a block decoder BD and transfer transistors TW0 to TW7, TS, and TD0 to TD4.

The block decoder BD decodes the block address BA. The block decoder BD applies a voltage corresponding to a “High (H)” level signal and a voltage corresponding to a “Low (L)” level signal to a transfer gate line BLKSEL based on a result of decoding the block address BA.

For example, the transfer transistors TW0 to TW7, TS, and TD0 to TD4 are N-channel Metal-Oxide-Semiconductor field effect transistors (MOSFET) having high breakdown voltage (high dielectric breakdown voltage). For example, a MOSFET with high breakdown voltage refers to a MOSFET with a gate insulation layer/film with a physical film thickness of 10 nm or more. The voltage between the gate and the source of the high breakdown voltage N-channel MOSFET may be, for example, a voltage of 10 V or more. Hereinafter, a transistor having a high breakdown voltage is referred to as a high breakdown voltage transistor.

The transfer transistors TW0 to TW7 (also referred to as word line switches) are respectively associated with the word lines WL0 to WL7. In the following description, when the transfer transistors TW0 to TW7 are not distinguished, the transfer transistors are simply referred to as the transfer transistors TW.

The transfer transistors TS, TD0 to TD4 are respectively associated with the select gate lines SGS, and SGD0 to SGD4. In the following description, when the transfer transistors TD0 to TD4 are not distinguished, the transfer transistors are simply referred to as the transfer transistors TD.

Each of the transfer transistors TW0 to TW7, TS, and TD0 to TD4 connects the driver circuit 14 to the corresponding blocks BLK via signal lines CG0 to CG7, CGS, and CGD0 to CGD4. In the following description, when the signal lines CG0 to CG7, CGS, and CGD0 to CGD4 are not distinguished, the signal lines are simply referred to as the signal line CG.

In each row decoder RD, a gate of the transfer transistor TD is connected to the transfer gate line BLKSEL. One end (one node) of each transfer transistor TD is connected to the driver circuit 14 via one corresponding signal line CG among the signal lines CGD0 to CGD4. The other end (e.g., the other node) of the transfer transistor TD is connected to one corresponding select gate line SGD among the select gate lines SGD0 to SGD4.

A gate of the transfer transistor TW is connected to the transfer gate line BLKSEL. One end of each transfer transistor TW is connected to the driver circuit 14 via one corresponding signal line CG among the signal lines CG0 to CG7. The other end of each transfer transistor TW is connected to one corresponding word line WL among the word lines WL0 to WL7.

A gate of the transfer transistor TS is connected to the transfer gate line BLKSEL. One end of the transfer transistor TS is connected to the driver circuit 14 via the signal line CGS. The other end of the transfer transistor TS is connected to the select gate line SGS.

When a “H” level signal (the ON voltage of the transistor) is applied to the transfer gate line BLKSEL, the transfer transistors TW, TS and TD are turned on. As a result, voltages of the signal lines CG0 to CG7, CGS, and CGD0 to CGD4 are transferred to the word lines WL0 to WL7, the select gate lines SGS, and the select gate lines SGD0 to SGD4 via the transfer transistors TW0 to TW7, TS, and TD0 to TD4 that are in the ON state. When a “L” level signal (the OFF voltage of the transistor) is applied to the transfer gate line BLKSEL, the transfer transistors TW, TS and TD are turned off. As a result, the signal lines CG0 to CG7, CGS, and CGD0 to CGD4 are electrically isolated from the word lines WL0 to WL7, the select gate lines SGS, and the select gate lines SGD0 to SGD4 by the transfer transistors TW0 to TW7, TS, TD0 to TD4, and the like, that are in the OFF state.

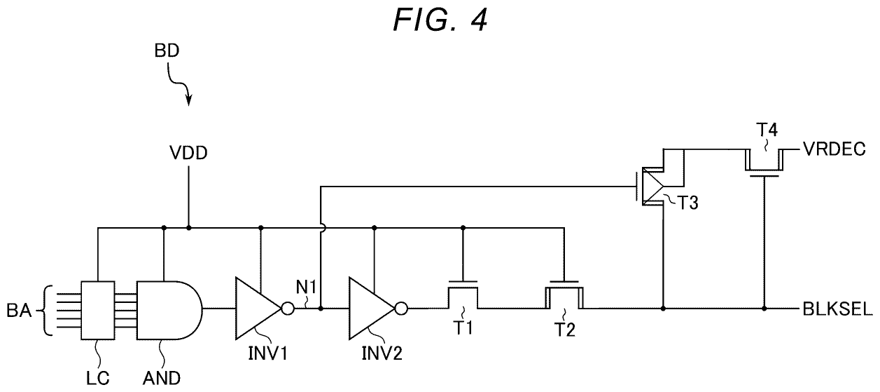

FIG. 4 is a circuit diagram showing a circuit configuration of the block decoder BD in the memory device 1.

As shown in FIG. 4, the block decoder BD includes a logic circuit LC, an AND circuit AND, inverters INV1 and INV2, and transistors T1, T2, T3, and T4.

The transistors T1, T2, and T4 are N-channel MOSFETs. The transistor T3 is a P-channel MOSFET. The transistors T2, T3, and T4 are MOSFETs with high breakdown voltage. A physical film thickness of each gate insulation layer of the transistors T2, T3, and T4 is thicker than a physical film thickness of the gate insulation layer of the transistor T1. The physical film thickness of each gate insulation layer of the transistors T2, T3, and T4 is, for example, 10 nm or more. Each gate-source voltage of the transistors T2, T3, and T4 may be, for example, a voltage of 10 V or more. The physical film thickness of the gate insulation layer of the transistor T1 is less than, for example, 10 nm. The gate-source voltage of the transistor T1 is, for example, a voltage lower than 10 V.

A plurality of first nodes of the logic circuit LC receive the block address BA from the address register 12. A second node of the logic circuit LC receives, for example, a supply voltage VDD. The logic circuit LC is driven by the supply voltage VDD. Each of a plurality of third nodes of the logic circuit LC outputs a signal based on the block address BA. A 1-bit signal of the block address BA is supplied to each of the first nodes of the logic circuit LC. When the block address BA input to the logic circuit LC is the block address BA allocated to the block BLK corresponding to the logic circuit LC, a “H” level signal is output from the third node of the logic circuit LC. When the block address BA input to the logic circuit LC is not the block address BA allocated to the block BLK corresponding to the logic circuit LC, a “L” level signal is output from the third node of the logic circuit LC.

A plurality of first nodes of the AND circuit AND are connected to the plurality of third nodes of the logic circuit LC, respectively. A second node of the AND circuit AND receives the supply voltage VDD. The AND circuit AND is driven by the supply voltage VDD. A third node of the AND circuit AND outputs a signal based on a logical AND operation of the signal output from each of the third nodes of the logic circuit LC. When the block address BA supplied to the block decoder BD is a block address allocated to the corresponding block BLK, the AND circuit AND outputs a “H” level signal from the third node. When the block address BA supplied to the block decoder BD is not a block address allocated to the corresponding block BLK, the AND circuit AND outputs a “L” level signal from the third node.

A first node of the inverter INV1 is connected to the third node of the AND circuit AND. A second node of the inverter INV1 receives the supply voltage VDD. The inverter INV1 is driven by the supply voltage VDD. A third node of the inverter INV1 is connected to a node N1. The third node of the inverter INV1 outputs an inversion signal (inverted signal) of the signal output from the third node of the AND circuit AND.

A first node of the inverter INV2 is connected to the node N1. A second node of the inverter INV2 receives the supply voltage VDD. The inverter INV2 is driven by the supply voltage VDD. A third node of the inverter INV2 outputs an inversion signal (inverted signal) of the signal output from the third node of the inverter INV1.

A first node of the transistor T1 is connected to the third node of the inverter INV2. A second node of the transistor T1 is connected to the transistor T2. A gate of the transistor T1 receives the supply voltage VDD.

A first node of the transistor T2 is connected to the second node of the transistor T1. A second node of the transistor T2 is connected to the transfer gate line BLKSEL. A gate of the transistor T2 receives the supply voltage VDD.

A first node of the transistor T3 is connected to the transfer gate line BLKSEL. A second node of the transistor T3, together with a back gate of the transistor T3, is connected to the transistor T4. The gate of the transistor T3 is connected to the node N1.

A first node of the transistor T4 is connected to the second node of the transistor T3 and the back gate of the transistor T3. A second node of the transistor T4 is connected to a node VRDEC. A gate of the transistor T4 is connected to the transfer gate line BLKSEL.

A high voltage (“H” level signal) is applied to the node VRDEC. The high voltage applied to the node VRDEC is a voltage set such that each of transfer transistors TW, TS, and TD can transfer the voltage supplied to the corresponding signal line CG to the word line WL, the select gate line SGS, and the select gate line SGD.

The transistors T3 and T4 are turned on when the AND circuit AND outputs a “H” level signal. The node VRDEC is connected to the transfer gate line BLKSEL via the transistors T3 and T4 in an ON state.

When the node VRDEC is connected to the transfer gate line BLKSEL via the transistors T3 and T4 in the ON state, a high voltage for driving the transfer transistors TW, TS and TD is supplied to the transfer gate line BLKSEL.

When the AND circuit AND outputs a “L” level signal, the node VRDEC is electrically isolated from the transfer gate line BLKSEL by the transistors T3 and T4 in the OFF state. In this case, a voltage corresponding to the “L” level signal output from the inverter INV2 is supplied to the transfer gate line BLKSEL.

According to the configuration described above, the block decoder BD outputs a “H” level signal to the transfer gate line BLKSEL when the corresponding block BLK is selected. The block decoder BD outputs a “L” level signal to the transfer gate line BLKSEL when the corresponding block BLK is not selected.

As a result, in the memory device 1, the selection and non-selection of blocks BLK within the memory cell array 10 is controlled.

### (a-2) Structure

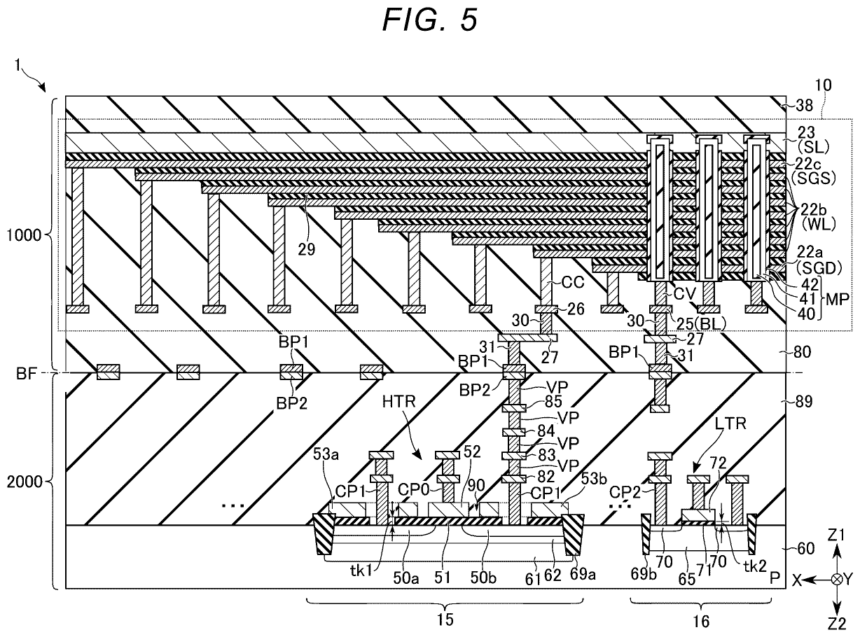

FIG. 5 is a cross-sectional view schematically showing an example of a structure of the memory device 1.

As shown in FIG. 5, the memory device 1 has a structure in which semiconductor chips 1000 and 2000 are bonded.

The semiconductor chip 1000 is provided with the memory cell array 10 of the memory device 1. A plurality of pads BP1 (electrodes) are provided on one side of the semiconductor chip 1000.

The semiconductor chip 2000 is provided with the peripheral circuit PERI of the memory device 1. A plurality of pads BP2 (electrodes) are provided on one side of the semiconductor chip 2000.

A surface of the semiconductor chip 1000 on which the pads BP1 are provided is bonded to a surface of the semiconductor chip 2000 on which the pads BP2 are provided. In the memory device 1 with this bonded structure, the two semiconductor chips 1000 and 2000 are brought into contact with each other at a surface BF (hereinafter referred to as a bonding surface) between the semiconductor chips 1000 and 2000.

At the bonding surface BF, the pads BP1 of the semiconductor chip 1000 are brought into contact with the pads BP2 of the semiconductor chip 2000. The pads BP1 can be connected to the pads BP2 by covalent bonding or the like that occurs between the materials forming the pads BP1 and BP2. The pads BP1 and BP2 can be conductors including copper (Cu). The pads BP1 and BP2 include active pads connected to device (wiring) or circuit components and dummy pads not connected to the device (wiring) or circuit components.

Hereinafter, certain directions parallel to the bonding surface BF are referred to as X directions and Y directions. The Y direction intersects the X direction. A direction that is orthogonal to the bonding surface BF and goes from the semiconductor chip 2000 toward the semiconductor chip 1000 is referred to as a Z1 direction. A direction that is orthogonal to the bonding surface BF and goes from the semiconductor chip 1000 toward the semiconductor chip 2000 is referred to as a Z2 direction. When the Z1 direction and the Z2 direction are not distinguished, the direction orthogonal to the bonding surface BF is referred to as the Z direction.

In the semiconductor chip 1000, the memory cell array 10 includes a plurality of conductive layers 22 (e.g., 22a, 22b, 22c), conductive layers 23, 25, 26 and 27, memory pillars MP, contacts CC and CV, plugs 30 and 31, a plurality of insulating layers 29, and insulating layers 38 and 80.

The conductive layers 22 and 23 are arranged in the Z direction. The insulating layers 29 are provided between adjacent conductive layers 22 and as well as between conductive layer 23 and an adjacent conductive layer 22 in the Z direction. The conductive layers 22 and insulating layers 29 are alternately stacked with each other in the Z direction.

A plurality of conductive layers 22a are provided between the lowest conductive layer 22b and the bonding surface BF in the Z direction. The plurality of conductive layers 22a are separated (divided) in the Y direction from each other. Each conductive layer 22a is, for example, a plate-like layer extending along an XY plane. Each of the conductive layers 22a is used as the select gate line SGD. The conductive layer 22a comprises, for example, tungsten.

A plurality of conductive layers 22b are stacked on the conductive layer 22a in the Z1 direction. The conductive layer 22b is, for example, a plate-like layer extending along the X-Y plane. A plurality of stacked conductive layers 22b are used as word lines WL7 to WL0 in order from the bonding surface BF side. The conductive layer 22b comprises, for example, tungsten.

The conductive layer 22c is, for example, a plate-like layer extending along the X-Y plane. The conductive layer 22c is used as the select gate line SGS. The conductive layer 22c comprises, for example, tungsten.

The conductive layer 23 is provided above the conductive layer 22a in the Z1 direction. The conductive layer 23 is, for example, a plate-like layer extending along the X-Y plane. The conductive layer 23 is used as a source line SL. The conductive layer 23 comprises, for example, silicon doped with phosphorus.

In some examples, conductive layer 23 may be a stacked film including a silicon layer and a metal layer.

An insulating layer 38 is provided on the conductive layer 23.

A stacked body including the plurality of conductive layers 22 is processed into a stepped shape at an end in the X direction. As a result, each of the conductive layers 22 includes a portion (hereinafter referred to as a terrace) that is not covered by the other conductive layers 22 on a surface of the conductive layer 22 facing in the Z2 direction.

A contact CC is provided on the surface of the conductive layer 22 facing the Z2 direction to contact the terrace of the conductive layer 22. The contact CC is connected to the conductive layer 22. The conductive layer 22 is connected to the pad BP1 via the contact CC, one or more plugs 30 and 31 (vias), and one or more conductive layers 26 and 27.

A plurality of conductive layers 25 are provided between the conductive layer 22a and the bonding surface BF. The plurality of conductive layers 25 are spaced from each other along the X direction. Each conductive layer 25 is, for example, a linear layer extending in the Y direction. The conductive layers 25 are used as the bit lines BL. Each conductive layer 25 is connected to a corresponding memory pillar MP via the contact CV. The conductive layer 25 is connected to the pad BP1 via the contact CV, one or more plugs 30 and 31, and one or more conductive layers 27. The conductive layer 25 comprises, for example, copper.

An insulating layer 80 covers the conductive layers 22, 23, and 25. A surface of the insulating layer 80 facing the Z2 direction corresponds to the bonding surface BF. The pads BP, the contacts CC and CV, the plugs 30 and 31, and the conductive layers 26 and 27 are provided in the insulating layer 80.

The memory pillars MP are cylindrical structures extending in the Z direction. The memory pillars MP are provided in the stacked body that includes the conductive layer 22. The memory pillars MP are formed extending through the plurality of conductive layers 22. An end of the memory pillar MP in the Z1 direction reaches into the conductive layer 23.

For example, the memory pillar MP includes a core layer 40, a semiconductor layer 41, and a stacked film 42. The core layer 40 extends along the Z direction. An end of the core layer 40 in the Z1 direction reaches into the conductive layer 23. The semiconductor layer 41 covers a periphery of the core layer 40. A portion of the semiconductor layer 41 is in contact with the conductive layer 23 at an end of the memory pillar MP in the Z1 direction. The stacked film 42 covers a side surface and a bottom surface (e.g., a surface in the Z1 direction) of the semiconductor layer 41 except the portion that is in contact with the semiconductor layer 41 and the conductive layer 23. The core layer 40 comprises, for example, an insulator such as silicon oxide. For example, the semiconductor layer 41 is silicon.

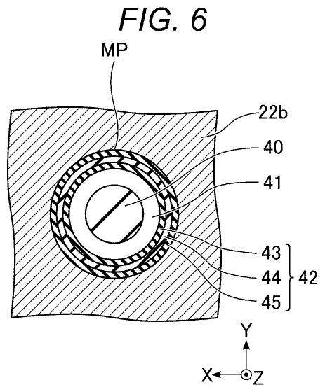

FIG. 6 is a cross-sectional view showing an example structure of the memory pillar MP in the memory device 1 according to the present embodiment. FIG. 6 shows a cross-sectional structure of the memory pillar MP in a layer parallel to the bonding surface BF and including the conductive layer 22b.

In FIG. 6, the stacked film 42 comprises a tunnel insulating film 43, a charge trap film 44 (charge storage layer), and a block insulating film 45.

In the cross section including the conductive layer 22b, the core layer 40 is provided in the center part of the memory pillar MP. The semiconductor layer 41 surrounds a side surface of the core layer 40. The tunnel insulating film 43 surrounds the side surface of the semiconductor layer 41. The charge trap film 44 surrounds a side surface of the tunnel insulating film 43. The block insulating film 45 surrounds a side surface of the charge trap film 44. The conductive layer 22b surrounds a side surface of the block insulating film 45. The tunnel insulating film 43 comprises, for example, silicon oxide. The charge trap film 44 comprises, for example, silicon nitride. For example, the block insulating film 45 is silicon oxide or aluminum oxide.

In each memory pillar MP, the semiconductor layer 41 is used as a channel region (e.g., current path) of the memory cells MT and the select transistors ST1 and ST2. The charge trap film 44 is used as a charge storage layer of the memory cells MT. The memory device 1 allows current to flow through the semiconductor layer 41 of the memory pillar MP between the bit line BL and the source line SL by turning on the memory cells MT and the select transistors ST1 and ST2.

A portion where the memory pillar MP and the conductive layer 22a intersect each other serves as the select transistor ST1. A portion where the memory pillar MP and one conductive layer 22b intersect each other serves as one memory cell MT. A portion where the memory pillar MP and the conductive layer 22c intersect each other serves as the select transistor ST2.

Each memory cell MT may store one or more bits of data by associating a threshold voltage of the memory cell MT with the data to be stored.

Returning to FIG. 5, the semiconductor chip 2000 will be described.

The semiconductor chip 2000 includes transistors HTR and LTR of peripheral circuits PERI for components such as the sequencer 13, the row control circuit 15, and the sense amplifier circuit 16.

The semiconductor chip 2000 includes a semiconductor substrate 60, transistors HTR and LTR, contacts CP0, CP1, and CP2, a plurality of plugs VP, conductive layers 82 83, 84, and 85, and an insulating layer 89.

The semiconductor substrate 60 is a silicon substrate, for example. The insulating layer 89 is provided on a surface of the semiconductor substrate 60 facing the Z1 direction. The insulating layer 89 provides a multilayer wiring structure that comprises a plurality of insulating films (layers) and the conductive layers 82 83, 84, and 85. The insulating layer 89 covers the conductive layers 82 83, 84, and 85, and the plugs VP provided above the transistors HTR and LTR, and the semiconductor substrate 60. A surface of the insulating layer 89 facing the Z1 direction corresponds to the bonding surface BF.

The transistors HTR and LTR are provided on a surface (upper surface) of the semiconductor substrate 60 facing the Z1 direction. The transistor HTR can be a MOSFET with high breakdown voltage. The transistor LTR can be a MOSFET with low breakdown voltage. The breakdown voltage of the transistor LTR (dielectric breakdown voltage) is lower than the breakdown voltage of the transistor HTR.

FIG. 5 shows cross sections of the transistors HTR and LTR. In FIG. 5, the channel length direction of the transistors HTR and LTR is along the X direction. However, depending on the layout of the transistors HTR and LTR on the semiconductor substrate 60, the channel length direction of the transistors HTR and LTR may be along the Y direction or otherwise.

For example, the transistor LTR is used for the sequencer 13 and the sense amplifier circuit 16. The transistor LTR is provided in an active region partitioned by an insulator 69b.

The transistor LTR is an N-channel or P-channel MOSFET of a planar structure. The transistor LTR includes two source/drain layers 70, a gate insulation layer 71, and a gate electrode 72.

The two source/drain layers 70 (e.g., diffusion layers, impurity regions) are provided in a well region 65 of the semiconductor substrate 60. The gate insulation layer 71 is provided on a channel region between the two source/drain layers 70. The gate electrode 72 is provided on the gate insulation layer 71. The gate electrode 72 faces the channel region via the gate insulation layer 71. The gate insulation layer 71 has a film thickness tk2 (physical thickness). For example, the film thickness tk2 of the gate insulation layer 71 is, for example, 1 nm to 5 nm.

Each contact CP2 is provided on the source/drain layer 70 and the gate electrode 72. The source/drain layer 70 and the gate electrode 72 are connected to a plurality of conductive layers 82 and 83 of the multilayer wiring structure via the contact CP2. The conductive layers 82 and 83 in different layers are connected via the plugs VP.

The low breakdown voltage transistor LTR may be provided on a semiconductor chip different from the semiconductor chip 2000 that has the high breakdown voltage transistor HTR. In this case, the memory device according to the present embodiment has a structure in which the semiconductor chip 1000 including the memory cell array 10, the semiconductor chip 2000 including the high breakdown voltage transistor HTR, and another semiconductor chip including the low breakdown voltage transistor LTR are bonded together.

The transistor HTR can be used for the row control circuit 15. The transistor HTR corresponds to the transfer transistor TW in this context. The transistor HTR is provided in an active region partitioned by an insulator 69a. For example, the transistor HTR is a MOSFET including a gate electrode 53 with a ring structure (or also referred to as a ring gate structure).

A transistor HTR having a ring structure includes at least two source/drain layers 50 (e.g., 50a and 50b), a gate insulation layer 51, and a plurality of gate electrodes 52 and 53 (e.g., 53a and 53b).

The two source/drain layers 50 are provided in a well region 62 of the semiconductor substrate 60. The well region 62 is provided in a well region 61 of the semiconductor substrate 60.

The gate insulation layer 51 is provided on a channel region between the two source/drain layers 50a and 50b and on the source/drain layers 50a and 50b. For example, the gate insulation layer 51 has a film thickness tk1. The film thickness tk1 (physical thickness) of the gate insulation layer 51 is greater than a film thickness tk2 of the gate insulation layer 71.

A gate electrode 52 is provided above the channel region via the gate insulation layer 51. The gate electrode 52 faces the channel region via the gate insulation layer 51. The gate electrode 52 is connected to the conductive layers 82 and 83 and the plug VP via the contact CP0.

Each gate electrode 53 has a ring-shaped structure when viewed from the Z direction. Each ring-shaped gate electrode 53 has an opening. That is, each ring-shaped gate electrode 53 surrounds an open region on the inside (interior) its ring shape in an XY-plane. The gate electrode 53a is provided above source/drain layer 50a via the gate insulation layer 51. The gate electrode 53b is provided above the source/drain layer 50b via the gate insulation layer 51. Each of these gate electrodes 53 faces a source/drain layer 50 via the gate insulation layer 51.

At a position corresponding to the opening of the gate electrode 53, the gate insulation layer 51 has an opening. The source/drain layer 50 is thus exposed in the opening of the gate electrode 53 and through an opening of the gate insulation layer 51.

A contact CP1 is provided on the source/drain layer 50 inside the opening of the gate insulation layer 51. The contact CP1 is connected to a pad BP1 via the conductive layers 82, 83, 84, and 85 and plugs VP. As a result, the transistor HTR is electrically connected to the conductive layer 22b (as a word line WL) via the bonded pads BP1 and BP2.

The gate electrode 52 is provided between the two gate electrodes 53a and 53b in the channel length direction (e.g., X direction) of the transistor HTR. In the following, the gate electrode 52 facing the channel region is also referred to as a main gate electrode 52. The ring-shaped gate electrode 53 is also referred to as a ring gate electrode 53.

A slit 90 is provided between the main gate electrode 52 and the ring gate electrode 53. As a result, the main gate electrode 52 is isolated from the ring gate electrode 53.

The high breakdown voltage transistor HTR having a ring gate electrode 53 is also referred to here as the ring gate transistor HTR.

The high breakdown voltage transistor HTR having a ring gate electrode 53 may achieve effects such as preventing the influence of an electric field propagating from conductive layers 82x and 83x above the gate electrodes 52 and 53 to the source/drain layer 50 and increasing the on-current by improving gate controllability. As a result, the high breakdown voltage transistor HTR having a ring gate electrode 53 may transfer a high voltage to the conductive layers 22 (e.g., the word lines WL or the select gate lines SGD and SGS) without impairing the stability and reliability of the operation of the transistor.

For example, a planar high breakdown voltage transistor without a ring gate electrode 53 may be used for transistors TD, TS, T2, T3, and T4. However, a ring gate transistor HTR may still be used for a high breakdown voltage transistor other than the transistor TW.

The memory device 1 according to the present embodiment may perform a write operation, a read operation, and an erase operation by conventional techniques.

According to the present embodiment, in the high breakdown voltage transistor HTR, a film thickness of a portion of the gate insulation layer 51 overlapping the slit 90 between the gate electrodes 52 and 53 is substantially equal to a film thickness of a portion of the gate insulation layer 51 overlapping the gate electrode 52.

### (a-2-1) Example Structure of High Breakdown Voltage Transistor

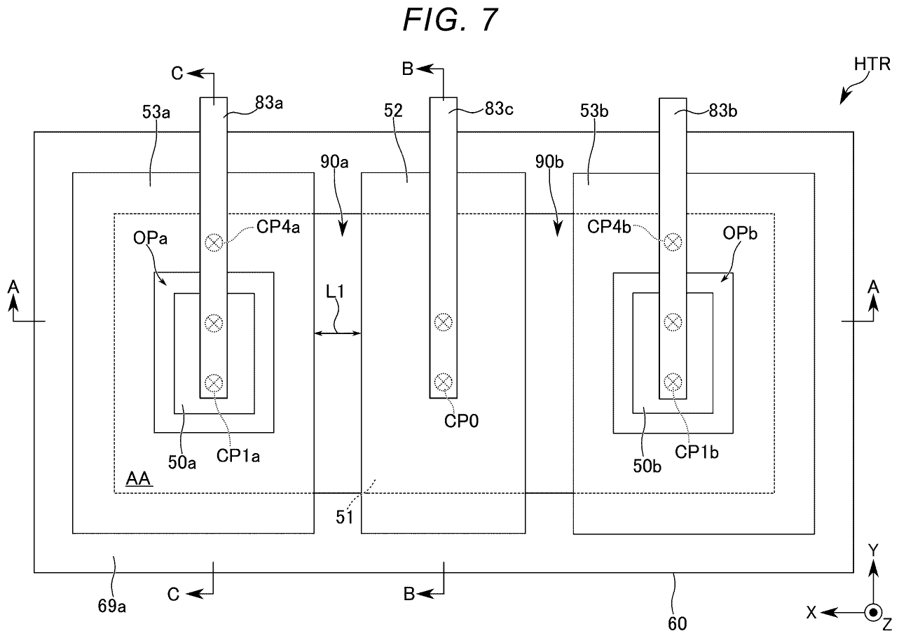

The example structure of a high breakdown voltage transistor HTR (ring gate transistor HTR) in the memory device 1 according to the present embodiment will be described with reference to FIGS. 7, 8, 9, and 10. FIGS. 7 to 10 show an example structure of the high breakdown voltage transistor HTR including a ring gate electrode 53 in the memory device 1.

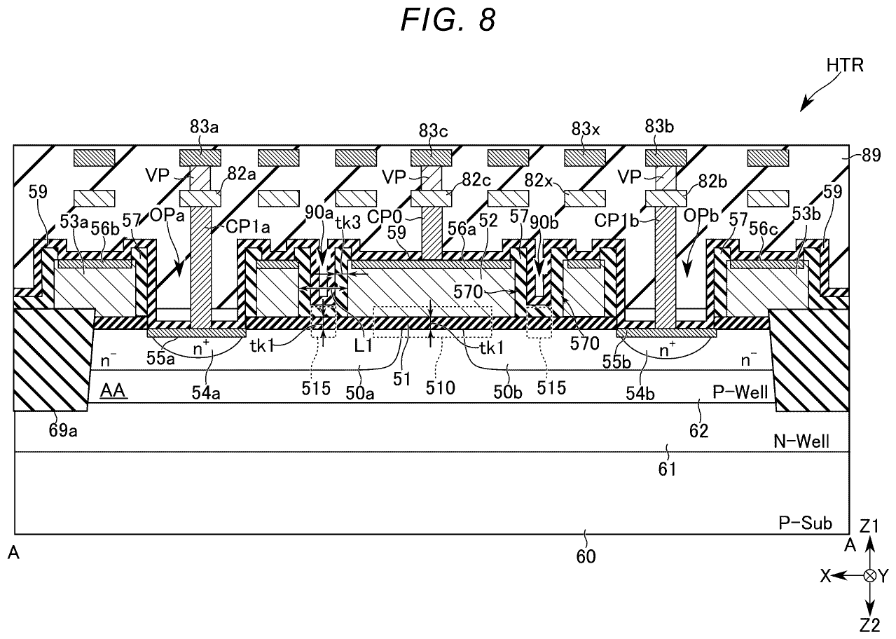

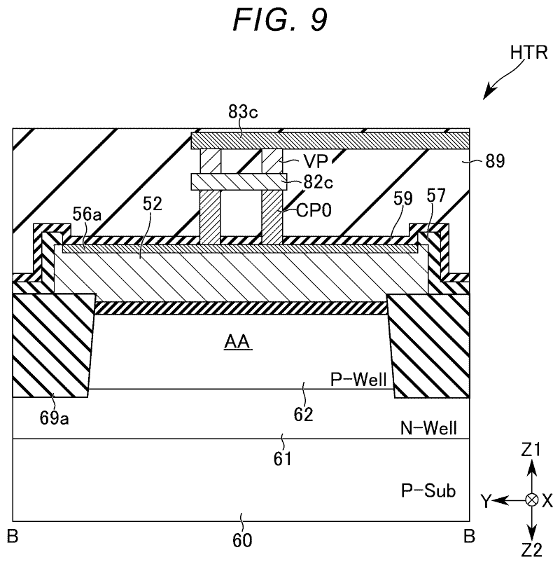

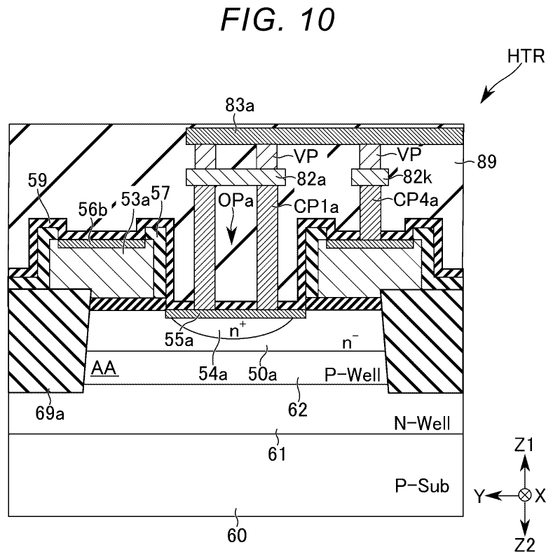

FIG. 7 is a top view (plan view) showing a planar structure of a ring gate transistor HTR in the memory device 1. FIG. 8 is a cross-sectional view of a ring gate transistor HTR taken along the A-A line of FIG. 7. FIG. 9 is a cross-sectional view of a ring gate transistor HTR taken along the B-B line of FIG. 7. FIG. 10 is a cross-sectional view of a ring gate transistor HTR taken along the C-C line of FIG. 7.

For example, a direction along the A-A line (e.g., X direction) corresponds to the channel length direction of the transistor HTR. For example, a direction along the B-B line and the C-C line (e.g., Y direction) corresponds to a channel width direction of the transistor HTR.

As shown in FIGS. 7 to 10, the ring gate transistor HTR is provided in an active region AA. The active region AA is partitioned by the insulator 69a for device isolation. The active region AA includes well regions 61 and 62. The well region 61 is provided in a p-type semiconductor substrate 60. The well region 61 is an n-type semiconductor region. The well region 62 is provided in the well region 61. The well region 62 is a p-type semiconductor region.

The gate insulation layer 51 is provided on the well region 62. The film thickness tk1 of the gate insulation layer 51 is, for example, 10 nm to 50 nm. A material of the gate insulation layer 51 is, for example, silicon oxide. For example, the gate insulation layer 51 covers an upper surface of the source/drain layer 50 and an upper surface of the channel region of the transistor HTR.

The main gate electrode 52 and the ring gate electrodes 53 are each provided on the gate insulation layer 51. The main gate electrode 52 is disposed between the two ring gate electrodes 53a and 53b in the X direction. Materials of the gate electrodes 52 and 53 are, for example, conductive polysilicon.

The main gate electrode 52 faces a channel region that is between the two source/drain layers 50a and 50b via (across) the gate insulation layer 51. The main gate electrode 52 has a square planar shape when viewed from the Z direction. The main gate electrode 52 extends lengthwise in the Y direction. The ends of the main gate electrode 52 in the Y direction are provided on the insulator 69a.

The ring gate electrode 53a faces the source/drain layer 50a via the gate insulation layer 51. The ring gate electrode 53b faces the source/drain layer 50b via the gate insulation layer 51. The outer ends of the ring gate electrode 53 in the Y direction are provided on the insulator 69a. One outer end of the ring gate electrode 53 on the side opposite to the main gate electrode 52 in the X direction is also provided on the insulator 69a.

A conductive layer 56a is provided on an upper surface (e.g., a surface facing the Z1 direction) of the main gate electrode 52. A material of the conductive layer 56a is, for example, silicide. The contact CP0 is provided on the conductive layer 56a of the main gate electrode 52. The contact CP0 is connected to a conductive layer 83c via a conductive layer 82c and a plug VP. As a result, the main gate electrode 52 is connected to the conductive layer 83c.

A conductive layer 56b is provided on an upper surface of the ring gate electrode 53a. A material of the conductive layer 56b is, for example, silicide. A contact CP4a is provided on the conductive layer 56b of the ring gate electrode 53a. The contact CP4a is connected to a conductive layer 83a via a conductive layer 82k and a plug VP. As a result, the ring gate electrode 53a is connected to the conductive layer 83a.

A conductive layer 56c is provided on an upper surface of the ring gate electrode 53b. A material of the conductive layer 56c is, for example, silicide. A contact CP4b is provided on the conductive layer 56c of the ring gate electrode 53b. The contact CP4b is connected to a conductive layer 83b via another conductive layer and a plug or the like. As a result, the ring gate electrode 53b is connected to the conductive layer 83b.

The conductive layers 56a, 56b, and 56c can be, or include, a silicide such as nickel silicide (NiSi₂), nickel platinum silicide (NiPtSi), or cobalt silicide (CoSi₂), for example. The conductive layers 56a, 56b, and 56c including silicide are also referred to as compound layers.

Slit 90a is provided between the main gate electrode 52 and the ring gate electrode 53a. The slit 90b is between the main gate electrode 52 and the ring gate electrode 53b. The slits 90 (90a and 90b) have a dimension L1 (slit width) in the X direction. The dimension L1 corresponds to spacing between the gate electrode 52 and the adjacent gate electrode 53.

The source/drain layers 50 (50a and 50b) are provided in the well region 62. For example, each source/drain layer 50 is an n⁻ type semiconductor region.

Diffusion layers 54 (54a and 54b) are provided in each source/drain layer 50. Each diffusion layer 54 is an n⁺ type semiconductor region. A concentration of n-type dopant in the diffusion layer 54 is thus higher than a concentration of n-type dopant of the source/drain layer 50.

Conductive layers 55 (e.g., 55a and 55b) are provided in a surface of the diffusion layer 54 facing the Z1 direction. A material of the conductive layer 55 is, for example, silicide. In general, materials similar to the material of the conductive layer 56 can be adopted for conductive layer 55. A conductive layer 55 including silicide is also referred to as a compound layer.

The diffusion layer 54 and the conductive layer 55 serve as a part of the source/drain layer 50. The diffusion layer 54 and the conductive layer 55 serve to reduce contact resistance between the contact CP0 and the source/drain layer 50.

A contact CP1 (CP1a and CP1b) is provided on the respective conductive layer 55 (55a, 55b) in the respective opening OP (OPa and OPb) of the ring gates electrode 53 (53a, 53b).

The contact CP1a is connected to the source/drain layer 50a via the conductive layer 55a and the diffusion layer 54a. The contact CP1a is connected to the ring gate electrode 53a via conductive layers 82a, 83a, and 82k, a plug VP, and the contact CP4a. As a result, the ring gate electrode 53a is electrically connected to the source/drain layer 50a.

The contact CP1b is connected to the source/drain layer 50b via the conductive layer 55b and the diffusion layer 54b. The contact CP1b is connected to the ring gate electrode 53b via conductive layers 82b and 83b, a plug VP, and the contact CP4b. As a result, the ring gate electrode 53b is electrically connected to the source/drain layer 50b.

A spacer layer 57 is provided on the main gate electrode 52 and the ring gate electrodes 53. The spacer layer 57 covers a side surface of the main gate electrode 52 and a side surface of the ring gate electrodes 53. The spacer layer 57 is a thick film having a relatively large film thickness. The spacer layer 57 is an insulating layer. For example, the material of the spacer layer 57 is the same as the material of the gate insulation layer 51. In this case, the material of the spacer layer 57 can be silicon oxide. A portion 570 of the spacer layer 57 covering the side surfaces of the gate electrodes 52 and 53 is also referred to as a sidewall spacer 570 (or sidewall layer).

In the slit 90 between the main gate electrode 52 and a ring gate electrode 53, a surface (e.g., upper surface, upper end) of the gate insulation layer 51 facing the Z1 direction is covered by the spacer layer 57.

In the slit 90, the spacer layer 57 on the side surface of the main gate electrode 52 is not in contact with the spacer layer 57 that covers the side surface of the ring gate electrode 53. That is, the slit 90 is not filled entirely by the spacer layer 57. That is, a film thickness tk3 of the spacer layer 57 is less than half of the dimension L1 of the slit 90 in the X direction. In the channel length direction of the high breakdown voltage transistor HTR, the film thickness tk3 of the spacer layer 57 on the side surface of the main gate electrode 52 and a film thickness tk3 of the spacer layer 57 on the side surface of the ring gate electrode 53 are each less than L1/2. That is, the sum of the film thicknesses tk3 of the spacer layer 57 along the X direction on the side surface of the main gate electrode 52 and the side surface of the ring gate electrode 53 is less than the dimension L1. Alternatively stated, the dimension L1 is greater than twice the film thickness tk3 (dimension L1>2×tk3).

A liner layer 59 covers the main gate electrode 52 and the ring gate electrode 53. The liner layer 59 is provided above the gate electrodes 52 and 53 via the spacer layer 57. For example, the liner layer 59 is provided on the spacer layer 57 and also on the conductive layers 55 and 56. That is, liner layer 59 is in direct contact with the conductive layers 55 and 56. A material of the liner layer 59 is, for example, silicon nitride. For example, a film thickness of the liner layer 59 is less than the film thickness tk3 of the spacer layer 57. For example, the liner layer 59 is a film providing a charge trap. Electrons are captured and stored in the liner layer 59 by the charge trap effect.

When the sidewall spacer 570 on the side surface of the main gate electrode 52 is not in contact with the sidewall spacer 570 on the side surface of the ring gate electrode 53, a gap (space) is provided between the sidewall spacers 570 facing each other in the slit 90. As such, the liner layer 59 can be provided in the gap left between the sidewall spacers 570 facing each other.

In the slit 90, the liner layer 59 is provided above the gate insulation layer 51 via the spacer layer 57. The liner layer 59 is also provided between the spacer layer 57 on the side surface of the main gate electrode 52 and the spacer layer 57 on the side surface of the ring gate electrode 53. In the slit 90, the liner layer 59 is interposed between the portions (sidewall spacers) 570 of the spacer layer 57 facing each other in the X direction. The liner layer 59 is thus provided between the side surface of the main gate electrode 52 and the side surface of the ring gate electrode 53 facing each other in the X direction.

In the slit 90, the spacer layer 57 is provided between the gate insulation layer 51 and the liner layer 59. The liner layer 59 in the slit 90 is isolated from the gate insulation layer 51 by the spacer layer 57. The position of a lower end (bottom) of the liner layer 59 in the slit 90 in the Z direction is higher than the position of lower ends (bottoms) of the gate electrodes 52 and 53 in the Z direction. In the present example, the position of the lower end (bottom) of the liner layer 59 in the slit 90 in the Z direction is lower than the position of upper ends (tops) of the gate electrodes 52 and 53 in the Z direction. As a more specific example, in the slit 90, the lower end of the liner layer 59 is at a position lower than the midpoint between the upper end (top) of the gate electrode 52 in the Z direction and the lower end (bottom) of the gate electrode 52 in the Z direction, but is higher than the lower end (bottom) of the gate electrode 52 in the Z direction.

For example, when a gap is left between the liner layer 59 on opposite sides of the slit 90, the insulating layer 89 can be provided on the liner layer 59 inside the slit 90 (that is, filling the gap). In the slit 90, a lower end (bottom) of the insulating layer 89 is at a position lower than the upper ends (tops) of the gate electrodes 52 and 53 in the Z direction (the semiconductor substrate 60 side). In this case, the interior of the slit 90 is filled with a combination of the spacer layer 57, the liner layer 59, and the insulating layer 89. Thus, across the slit 90, the spacer layer 57, the liner layer 59 and the insulating layer 89 are interposed between the main gate electrode 52 and the ring gate electrode 53.

In the memory device 1 according to the present embodiment, the gate insulation layer 51 of the high breakdown voltage transistor HTR with a ring gate structure has a substantially uniform film thickness tk1 on the semiconductor substrate 60. An upper surface of the gate insulation layer 51 (e.g., a surface on the side on which the gate electrodes 52 and 53 are provided) is flat.

The gate insulation layer 51 includes a portion 510 between the semiconductor substrate 60 and the gate electrode 52 (or the gate electrode 53) and a portion 515 in the slit 90 between the liner layer 59 (or the spacer layer 57) and the semiconductor substrate 60. The portions 510 and 515 are, however, one continuous layer.

The portion 515 aligns with the slits 90 (e.g., 90a and 90b) in the Z direction.

In the gate insulation layer 51, the film thickness tk1 of the portion 515 is substantially equal to the film thickness tk1 of the portion 510.

The position of an upper end (upper portion) of the portion 515 in the Z direction is level with the position of an upper end of the portion 510 in the Z direction. That is, a surface including the upper end of the portion 510 and an upper end of the portion 515 is flat.

A structure of the portion 515 in the slit 90a between the main gate electrode 52 and the ring gate electrode 53a is substantially the same as a structure of the portion 515 in the slit 90b between the main gate electrode 52 and the other ring gate electrode 53b. For example, the film thickness tk1 of the portion 515 in the slit 90a is equal to the film thickness tk1 of the portion 515 in the slit 90b.

As described above, the spacer layer 57 is provided on the upper end of the portion 515 of the gate insulation layer 51. In the slit 90, the spacer layer 57 is interposed between the liner layer 59 and the portion 515. The liner layer 59 is not in direct contact with the portion 515 due to the spacer layer 57 interposed between them.

In the present embodiment, the film thickness of the portion 515 in the slit 90 can be prevented from being reduced (eroded) during certain manufacturing methods described below by the presence of spacer layer 57. Accordingly, the upper end of the portion 515 of the gate insulation layer 51 does not retreat to the semiconductor substrate 60 side during manufacturing.

As a result, in the gate insulation layer 51 of the high breakdown voltage transistor HTR of the memory device 1, the film thickness of the portion 515 is kept the same as the film thickness of the portion 510.

Accordingly, the memory device 1 according to the first embodiment can improve the reliability of a device such as the high breakdown voltage transistor HTR.

### (b) Manufacturing Method

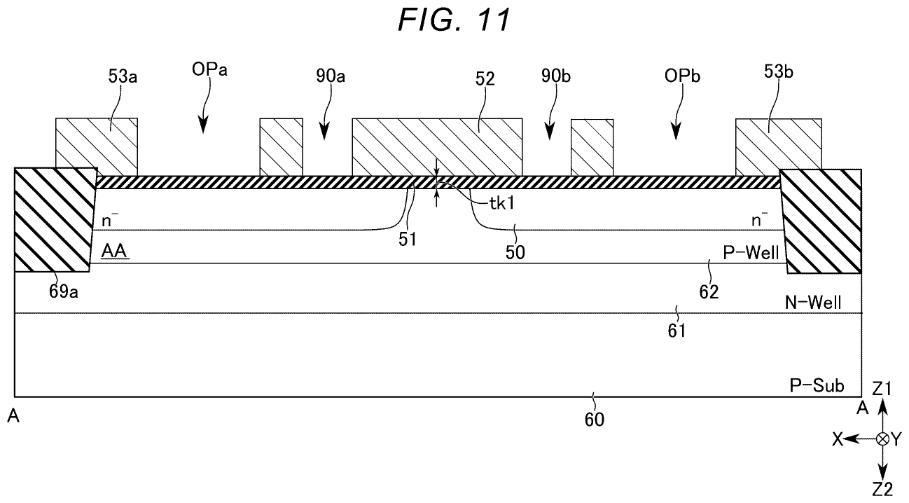

A manufacturing method of the memory device 1 according to the first embodiment will be described with reference to FIGS. 11 to 16.

FIGS. 11 to 16 are cross-sectional process diagrams showing a plurality of manufacturing processes in the manufacturing method of the memory device 1 according to the first embodiment. FIGS. 11 to 16 respectively show the manufacturing processes of the high breakdown voltage transistor HTR in the semiconductor chip 2000 including the peripheral circuit PERI. FIGS. 11 to 16 show cross sections along the channel length direction of the high breakdown voltage transistor HTR.

As shown in FIG. 11, the well region 61 and the insulator 69a are formed in the semiconductor substrate 60. Accordingly, the active region AA is partitioned in the semiconductor substrate 60. After the well region 62 is formed in the active region AA, two source/drain layers 50a and 50b are formed in the well region 62 by ion implantation, for example.

The gate insulation layer 51 is formed on the well region 62 by a thermal oxidation process or a film deposition process. The gate insulation layer 51 has the film thickness tk1. The gate insulation layer 51 is, for example, a silicon oxide layer.

The main gate electrode 52 and the ring gate electrode 53 (e.g., 53a and 53b) are formed on the gate insulation layer 51 by a known technique such as chemical vapor deposition (CVD), photolithography, and reactive ion etching (RIE). The gate electrodes 52 and 53 are, for example, silicon layers.

The ring gate electrodes 53 and the openings OP are formed respectively. The main gate electrode 52 is disposed in a region between the two ring gate electrodes 53a and 53b in the X direction.

The slits 90 (e.g., 90a and 90b) are formed between the main gate electrode 52 and the ring gate electrodes 53 by a gate processing on a conductive layer (e.g., a silicon layer).

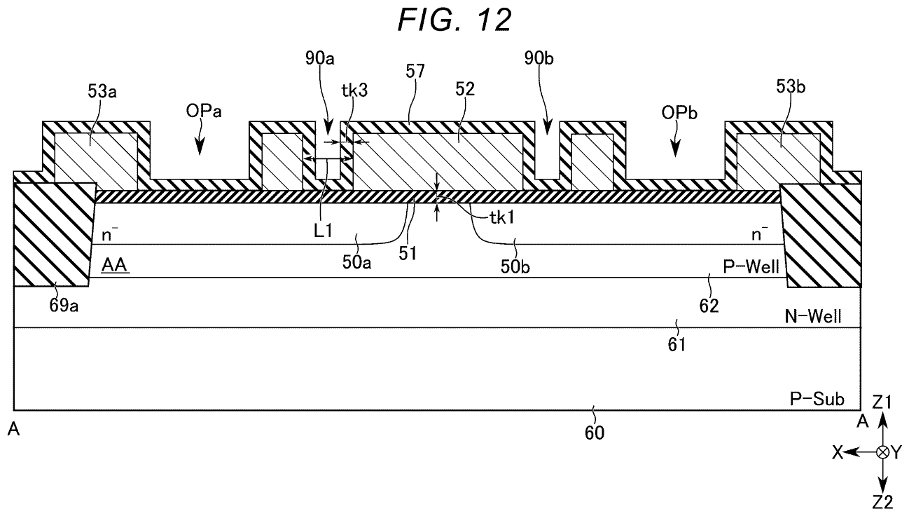

As shown in FIG. 12, the spacer layer 57 is formed on the gate electrodes 52 and 53 by film deposition process (e.g., CVD). The spacer layer 57 covers the upper and side surfaces of the gate electrodes 52 and 53. The spacer layer 57 is formed on the upper surface of the gate insulation layer 51 in the slits 90 and in the openings OP (OPa and OPb) of the ring gate electrodes 53. The film thickness tk3 (dimension along the X direction) of the spacer layer 57 on the side surfaces of the gate electrodes 52 and 53 is less than half of the dimension L1 of the slit 90 in the X direction (film thickness tk3<L1/2).

The spacer layer 57 (sidewall spacer) on the side surface of the main gate electrode 52 is not in contact with the spacer layer 57 on the side surface of the ring gate electrode 53. Accordingly, the interior of the slit 90 is not completely filled with the material of the spacer layer 57. A gap is left between the spacer layer 57 on the side surface of the main gate electrode 52 and the spacer layer 57 on the side surface of the ring gate electrode 53.

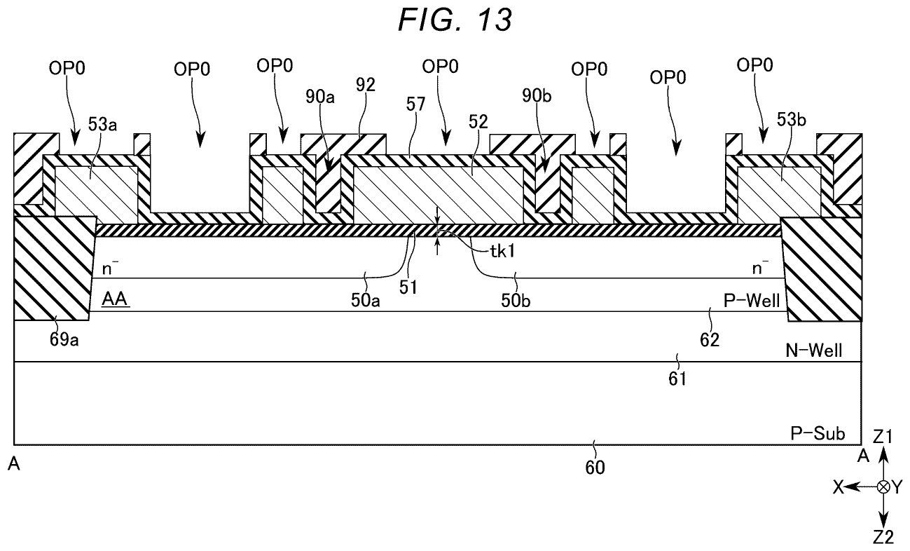

As shown in FIG. 13, a mask layer 92 is formed on the spacer layer 57 in a predetermined pattern by photolithography and etching.

Openings OP0 are formed in the mask layer 92 at positions corresponding to a region to be subjected to silicide process (e.g., a region where silicide is to be formed). Portions of spacer layer 57 are exposed through the openings OP0.

In the present embodiment, the mask layer 92 is provided covering the slits 90. For example, the mask layer 92 is provided inside the slit 90. As a result, the spacer layer 57 between the gate electrodes 52 and 53 is not exposed, but is covered with the mask layer 92.

Etching of the spacer layer 57 and the gate insulation layer 51 is performed based on the pattern of the mask layer 92.

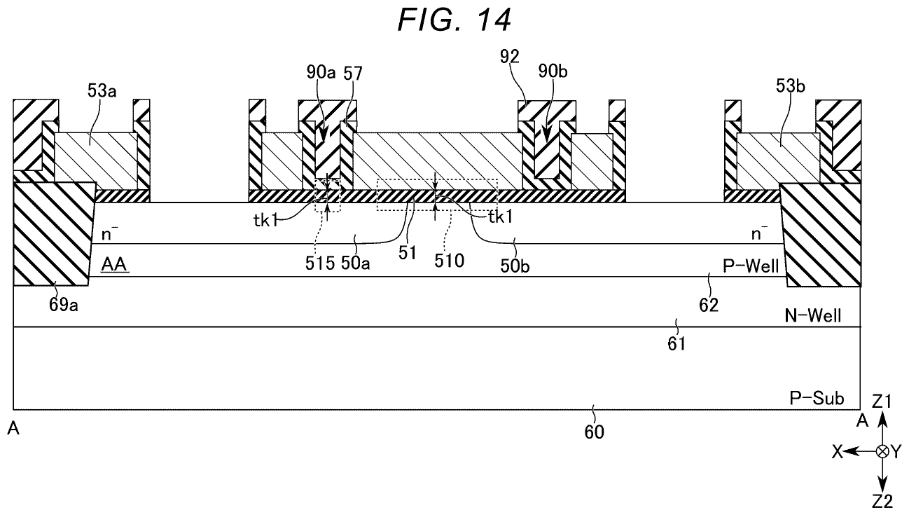

As shown in FIG. 14, portions of the gate insulation layer 51 and the spacer layer 57 are removed by etching.

Upper surfaces of the gate electrodes 52 and 53 and the upper surface of the source/drain layer 50 are exposed through the openings formed in the gate insulation layer 51 and the spacer layer 57.

In the present embodiment, the spacer layer 57 and the gate insulation layer 51 in the slit 90 remain between the adjacent gate electrodes 52 and 53 without being etched. In the slit 90, the upper surface (upper surface of the portion 515) of the gate insulation layer 51 remains covered with the spacer layer 57. The portion 515 of the gate insulation layer 51 at the position of the slit 90 maintains the film thickness tk1 from the time of the formation of the gate insulation layer 51, like the portion 510 of the gate insulation layer 51 overlapping the gate electrode 52.

After etching, the mask layer 92 is removed.

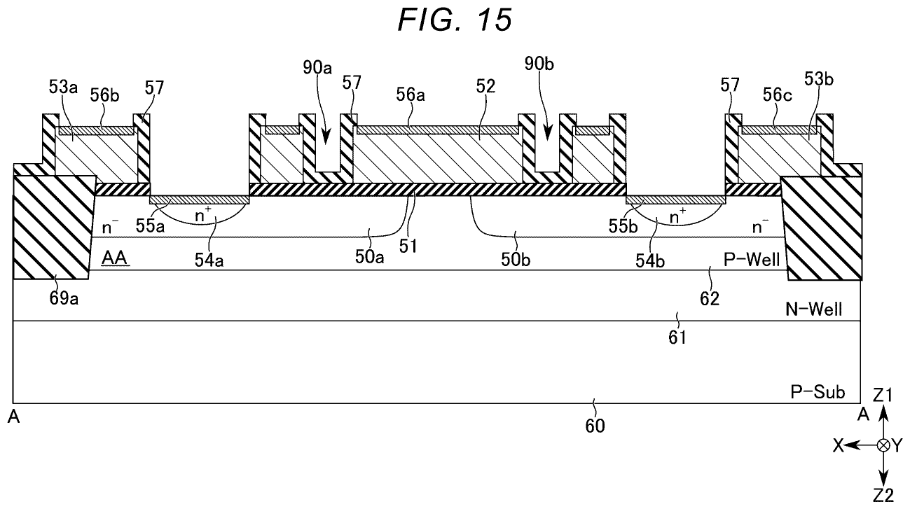

As shown in FIG. 15, the diffusion layers 54 (54a and 54b) are formed in the source/drain layer 50 by ion implantation. The ion implantation for forming the diffusion layers 54 may be performed before removing the mask layer 92 or before etching the gate insulation layer 51.

The conductive layers 55 and 56 including silicide portions are formed in a self-aligned manner on the upper surface of the source/drain layer 50 and the upper surface of the gate electrodes 52 and 53, respectively, by a so-called salicide process.

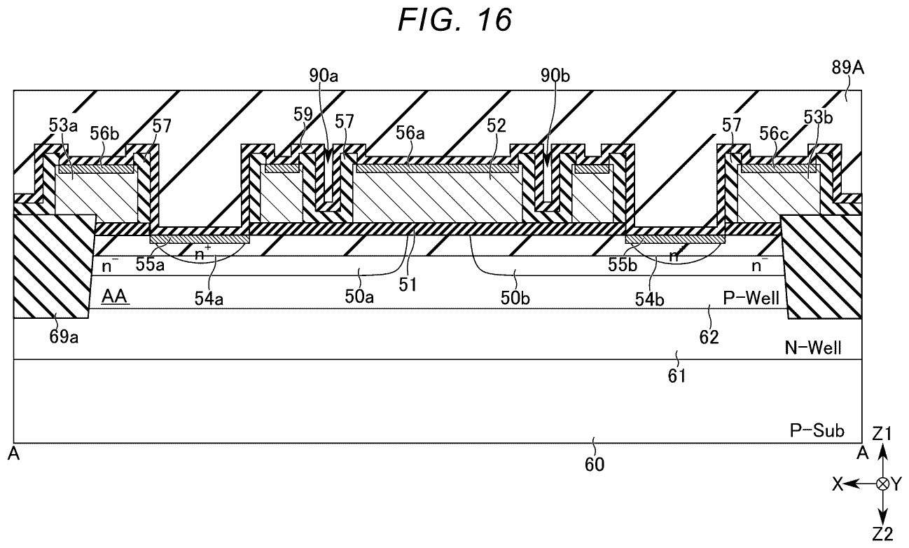

As shown in FIG. 16, the liner layer 59 is formed on the conductive layers 55 and 56 and on the spacer layer 57 by film deposition technique (e.g., CVD), covering the gate electrodes 52 and 53. The liner layer 59 is, for example, a silicon nitride layer.

In the slit 90, the liner layer 59 is formed on the spacer layer 57. The spacer layer 57 is provided between the liner layer 59 and the gate insulation layer 51. In the slit 90, the liner layer 59 is thus not in direct contact with the gate insulation layer 51.

An insulating layer 89A is formed on the liner layer 59 to cover the gate electrodes 52 and 53. In the slit 90, the insulating layer 89A is provided on the liner layer 59. The interior of the slit 90 is filled with the insulating layer 89A, the liner layer 59 and the spacer layer 57.

Then, as shown in FIGS. 7 to 10, the contacts CP0, CP1, and CP4, the conductive layers 82a, 82b, and 82c, the plugs VP, the conductive layers 83a, 83b, and 83c, and corresponding insulating layers are sequentially formed by a known technique.

In parallel with the formation of the high breakdown voltage transistor HTR, the low breakdown voltage transistor LTR is formed on the semiconductor substrate 60 by a manufacturing process common to the formation of the high breakdown voltage transistor HTR.

As a result, the semiconductor chip 2000 including the high breakdown voltage transistor HTR is formed.

The semiconductor chip 1000 including the memory cell array 10 is formed by a manufacturing process separate from that used for the formation of the semiconductor chip 200.

The semiconductor chip 2000 is ultimately bonded to the semiconductor chip 1000 so that the pad BP2 of the semiconductor chip 2000 is bonded to the pad BP1 of the semiconductor chip 1000. As a result, the transistors HTR and LTR of the semiconductor chip 2000 are electrically connected to the memory cell array 10 of the semiconductor chip 1000.

By the manufacturing process described above, the memory device 1 according to the first embodiment is completed.

### (c) Summary

The memory device 1 according to the first embodiment includes a high breakdown voltage transistor HTR including the main gate electrode 52 and the two ring gate electrodes 53.

A slit 90 is provided between the main gate electrode 52 and each ring gate electrode 53. A spacer layer 57 covering the side surfaces of the gate electrodes 52 and 53 is provided in the slit 90. In the slit 90, the liner layer 59 is provided on the spacer layer 57. The lower end of the liner layer 59 in the Z direction is positioned below the upper ends of the gate electrodes 52 and 53. The liner layer 59 comprises an insulating layer (for example, a silicon nitride layer) including a charge trap. In the slit 90, the spacer layer 57 is provided between the lower end of the liner layer 59 and the gate insulation layer 51.

In a conventional high breakdown voltage transistor, the interior of the slit is not blocked by the spacer layer during the process of forming the opening in the gate insulation layer, so the portion of the gate insulation layer at the position of the slit will also be etched when performing the etching process for forming the opening in the gate insulation layer. In this case, the upper surface of the portion of the gate insulation layer at the position of the slit retreats to the semiconductor substrate side.

A liner layer including silicon nitride is then formed on the spacer layer after the process of forming the opening in the gate insulation layer. When the slit between the gate electrodes is not blocked by the spacer layer, the liner layer is still provided in the slit. In this case, the liner layer will be in contact with the gate insulation layer.

When the upper surface of the gate insulation layer in the slit retreats to the semiconductor substrate side, the liner layer will extend closer to the semiconductor substrate at the position of the slit.

During the operation of such a conventional high breakdown voltage transistor, a charge trap (capture of electrons) may occur in the liner layer (silicon nitride layer) near the semiconductor substrate. As a result, the liner layer becomes charged. Charging of the liner layer in the high breakdown voltage transistor causes deterioration of the bias-temperature characteristics (BT characteristics) at the drain of the transistor. For this reason, the conventional high breakdown voltage transistor may experience reduced reliability during operation.

In the memory device 1 according to the first embodiment, the interior of the slit 90 (formed between the main gate electrode 52 and the ring gate electrode 53) is filled with the spacer layer 57 and the liner layer 59. For example, the insulating layer 89 (e.g., an interlayer insulating film) is further provided within the slit 90. The spacer layer 57, the liner layer 59, and the insulating layer 89 are thus interposed between the main gate electrode 52 and the ring gate electrode 53 in the channel length direction (X direction) of the transistor HTR.

In the high breakdown voltage transistor HTR of the memory device 1 according to the first embodiment, the film thickness tk1 of the portion 515 of the gate insulation layer 51 at the position of the slit 90 is equal to the film thickness tk1 of the portion 510 of the gate insulation layer 51 between the main gate electrode 52 and the semiconductor substrate 60.

As a result, in the memory device 1 according to the first embodiment, the high breakdown voltage transistor HTR can provide a relatively large distance between the liner layer 59 including silicon nitride and the semiconductor substrate 60.

In the high breakdown voltage transistor HTR of the memory device according to the first embodiment, in the slit 90, the spacer layer 57 is provided between the liner layer 59 and the gate insulation layer 51. As a result, the high breakdown voltage transistor HTR can have a further increase in the distance between the liner layer 59 and the semiconductor substrate 60.

As a result, in the memory device 1 according to the first embodiment, the high breakdown voltage transistor HTR can prevent the charge trapping in the liner layer 59 (including silicon nitride) during the operation of the transistor (e.g., transfer of high voltage).

Accordingly, the memory device 1 according to the first embodiment can prevent the deterioration of BT characteristics at the drain of the high breakdown voltage transistor HTR. Accordingly, the memory device 1 can have improved reliability of the high breakdown voltage transistor HTR.

As described above, the memory device 1 and the semiconductor device HTR according to the present embodiment can have provide improved device reliability.

### (2) Second Embodiment

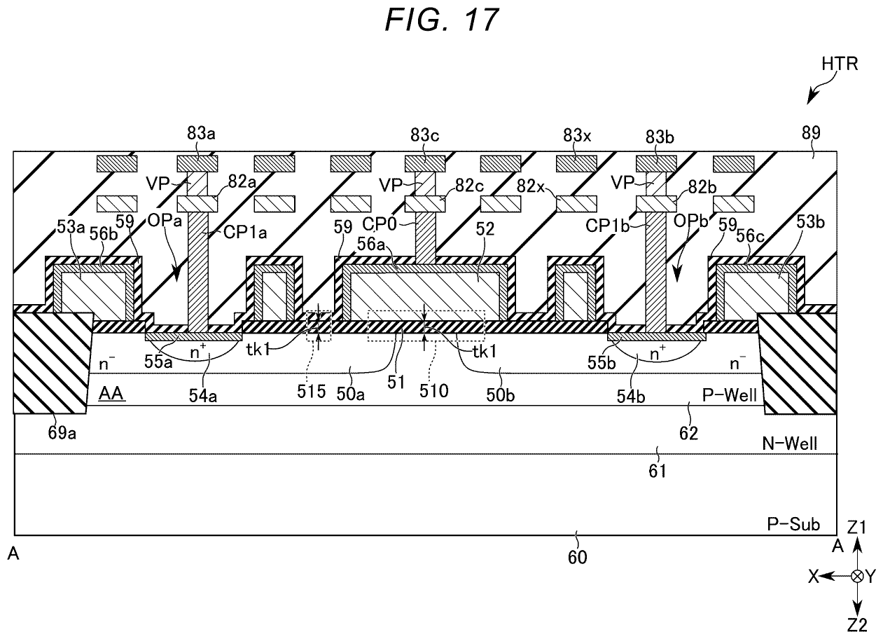

A memory device, a semiconductor device, and a manufacturing method of the memory device (or the semiconductor device) according to a second embodiment will be described with reference to FIGS. 17 to 21.

### (a) Example Configuration

FIG. 17 is a cross-sectional view showing an example structure of the memory device 1 according to the present embodiment. FIG. 17 shows a cross-sectional structure of the high breakdown voltage transistor HTR in the channel length direction in the memory device 1 according to the present embodiment.

As shown in FIG. 17, in the high breakdown voltage transistor HTR of the memory device 1 according to the present embodiment, the spacer layer is not provided on the gate electrodes 52 and 53.

For example, the conductive layer 55 is provided on the upper and side surfaces of the main gate electrode 52. The conductive layer 56 is provided on the upper and side surfaces of the ring gate electrode 53.

The liner layer 59 covers the upper and side surfaces of the gate electrodes 52 and 53 without the intervention of the spacer layer. The liner layer 59 is provided on the conductive layers 55 and 56. The position of the lower end of the liner layer 59 in the slit 90 in the Z direction is substantially the same as the position of the lower end of the gate electrode 52 in the Z direction.

In the slit 90, the liner layer 59 is in direct contact with the gate insulation layer 51. In the slit 90, the insulating layer 89 is provided on the liner layer 59. The interior of the slit 90 is filled (blocked) with the liner layer 59 and the insulating layer 89.

### (b) Manufacturing Method

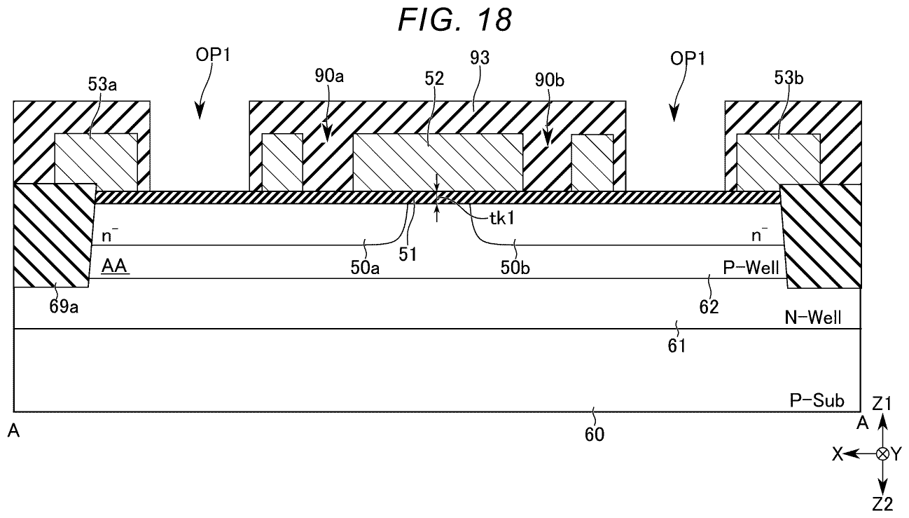

A manufacturing method of the memory device 1 according to the present embodiment will be described with reference to FIGS. 18 to 21.

FIGS. 18 to 21 are cross-sectional process diagrams showing a plurality of manufacturing processes in the manufacturing method of the memory device 1 according to the present embodiment. FIGS. 18 to 21 respectively show the manufacturing processes of the high breakdown voltage transistor HTR in the semiconductor chip 2000 including the peripheral circuit PERI. FIGS. 18 to 21 show cross sections along the channel length direction of the high breakdown voltage transistor HTR.

As shown in FIG. 18, similar to an embodiment described above, the gate electrodes 52 and 53 are formed on the gate insulation layer 51. In the present embodiment, the process of forming the spacer layer is not performed.

A mask layer 93 is formed on the gate insulation layer 51 and on the gate electrodes 52 and 53 to cover the gate electrodes 52 and 53, which do not have the spacer layer.

In a region where the diffusion layer 54 is to be formed, the opening OP1 is formed in the mask layer 93 by photolithography and etching. The opening OP1 is provided in the mask layer 93 to overlap the position of the opening OP of the ring gate electrode 53.

In the present embodiment, a region (e.g., slit 90) between the main gate electrode 52 and the ring gate electrode 53 is covered with the mask layer 93.

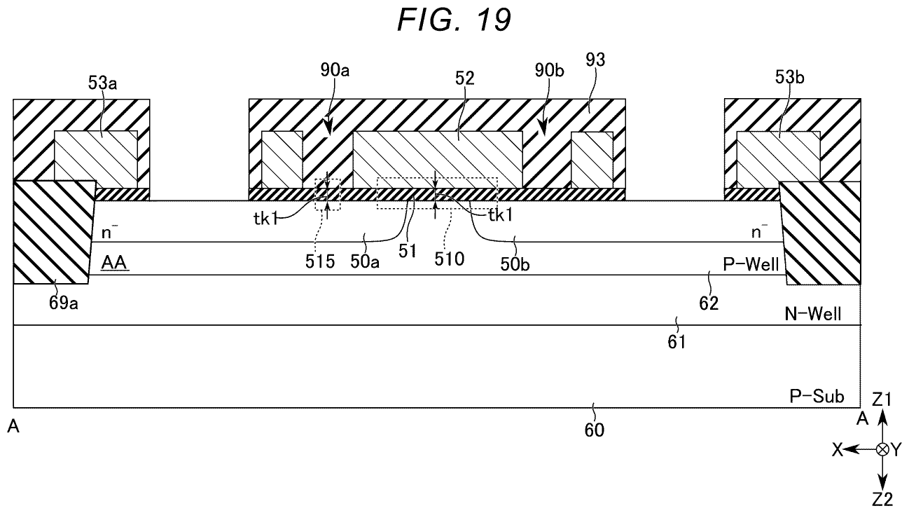

As shown in FIG. 19, the gate insulation layer 51 is removed by etching based on the pattern of the mask layer 93. As a result, the upper surface of the source/drain layer 50 is exposed.

The portion 515 of the gate insulation layer 51 in the slit 90 is covered with the mask layer 93. For this reason, the portion 515 is not etched. The portion 515 maintains its full, initial film thickness tk1 from the time of forming the gate insulation layer 51.

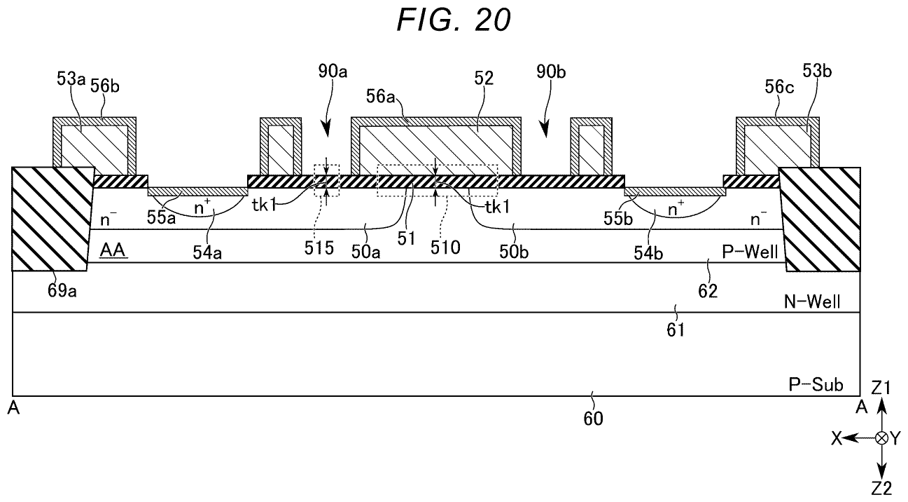

As shown in FIG. 20, the diffusion layer 54 is formed in the source/drain layer 50 by ion implantation.

The conductive layers 55 and 56 are formed on the gate electrodes 52 and 53 and on the diffusion layers 54 by a salicide process.

In the present example, because there is no spacer layer covering the side surfaces of the gate electrodes 52 and 53, the conductive layers 55 and 56 are formed not only on the upper surfaces of the gate electrodes 52 and 53, but also on the side surfaces of the gate electrodes 52 and 53.

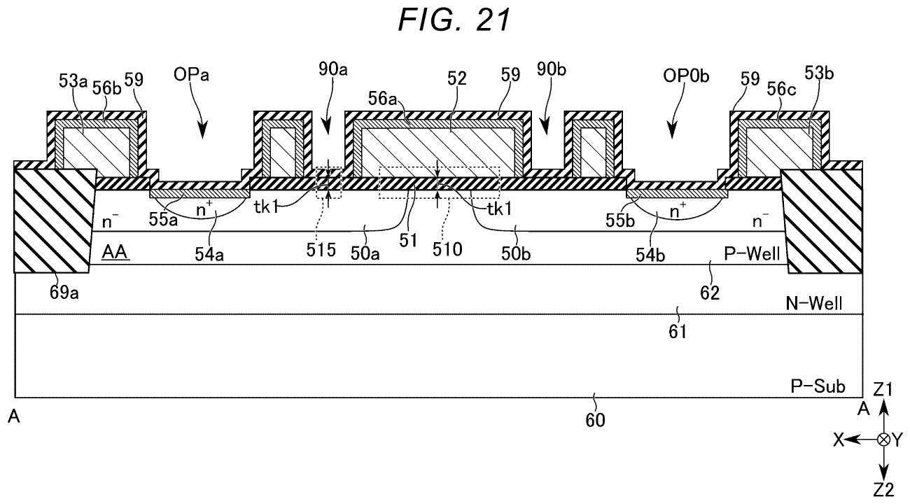

As shown in FIG. 21, the liner layer 59 is formed on the conductive layers 55 and 56, covering the gate electrodes 52 and 53. In the slit 90, the liner layer 59 is in direct contact with the gate insulation layer 51.

Then, similar to an embodiment described above, the contacts CP0, CP1, and CP4, the conductive layers 82a, 82b, and 82c, the plugs VP, the conductive layers 83a, 83b, and 83c and corresponding insulating layers are sequentially formed. The semiconductor chip 2000 including the formed high breakdown voltage transistor HTR is bonded to the semiconductor chip 1000.

By the manufacturing process described above, the memory device 1 according to the present embodiment is completed.

### (c) Summary

In the memory device 1 according to the present embodiment, the high breakdown voltage transistor HTR does not include a spacer layer (57) covering the gate electrodes 52 and 53. The liner layer 59 is thus in direct contact with the gate electrodes 52 and 53.

However, during the etching for forming the opening in the gate insulation layer 51, the slit 90 between the main gate electrode 52 and the ring gate electrode 53 is covered with the mask layer 93.

Accordingly, during the etching for forming the opening in the gate insulation layer 51, the portion 515 of the gate insulation layer 51 at the position of the slit 90 is not etched due to the presence of the mask layer 93 during this process. As a result, the portion 515 maintains its full initial film thickness tk1 from the time of forming the gate insulation layer 51, like the portion 510 below the gate electrodes 52 and 53.

Accordingly, in the memory device 1 according to the present embodiment, the high breakdown voltage transistor HTR can ensure a relatively large distance between the liner layer 59 including silicon nitride and the semiconductor substrate 60.

As a result, in the memory device 1 according to the present embodiment, the high breakdown voltage transistor HTR can prevent the deterioration of BT characteristics of the high breakdown voltage transistor that might otherwise be caused by the charge trapping in the liner layer 59.

As described above, the memory device 1 and the semiconductor device HTR according to the second embodiment can improve the device reliability.

### (3) Third Embodiment

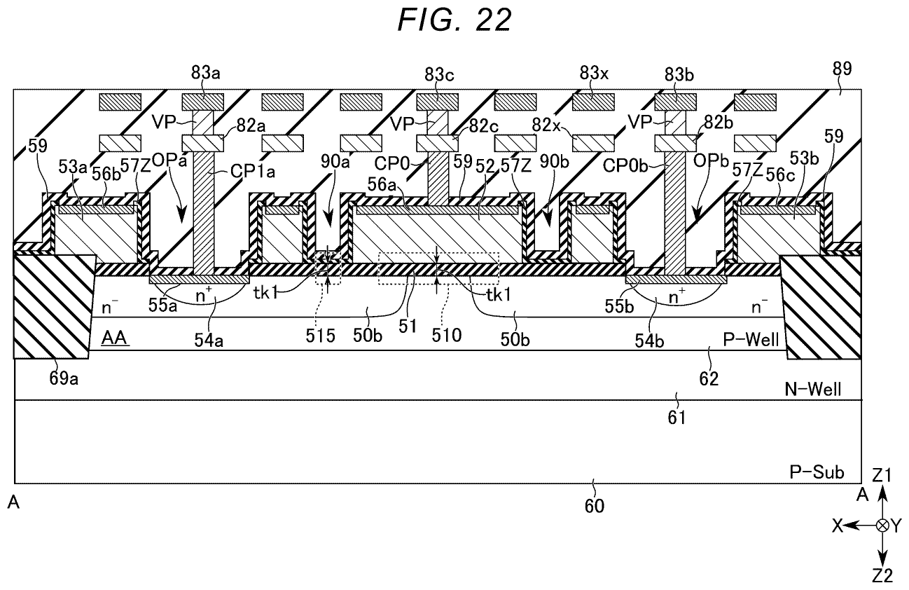

A memory device, a semiconductor device, and a manufacturing method of the memory device (or the semiconductor device) according to a third embodiment will be described with reference to FIGS. 22 to 24.

### (a) Example Configuration

FIG. 22 is a cross-sectional view showing an example configuration of the memory device 1 according to the present embodiment. FIG. 22 shows a cross-sectional structure of the high breakdown voltage transistor HTR in the channel length direction in the memory device 1 according to the present embodiment.

As shown in FIG. 22, in the memory device 1 according to the present embodiment, an insulating layer 57Z is provided between the gate electrodes 52 and 53 and the liner layer 59. The insulating layer 57Z is a layer for preventing silicidation of a specific portion (region) of the gate electrodes 52 and 53 and the source/drain layer 50. Hereinafter, the insulating layer 57Z is referred to as a block layer 57Z.

For example, the block layer 57Z is provided on the side surfaces of the gate electrodes 52 and 53. For example, the block layer 57Z conformally covers the gate electrodes 52 and 53. The block layer 57Z is a thin film. For example, the film thickness of the block layer 57Z is less than the film thickness of the liner layer 59. The film thickness of the block layer 57Z is, for example, about 10 to 20 nm.

The interior of the slit 90 is filled with the block layer 57Z, the liner layer 59, and the insulating layer 89.

### (b) Manufacturing Method

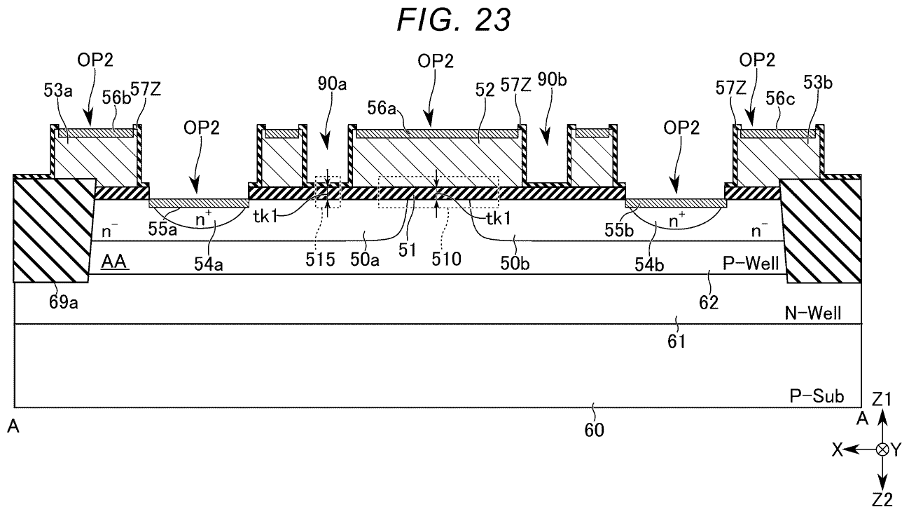

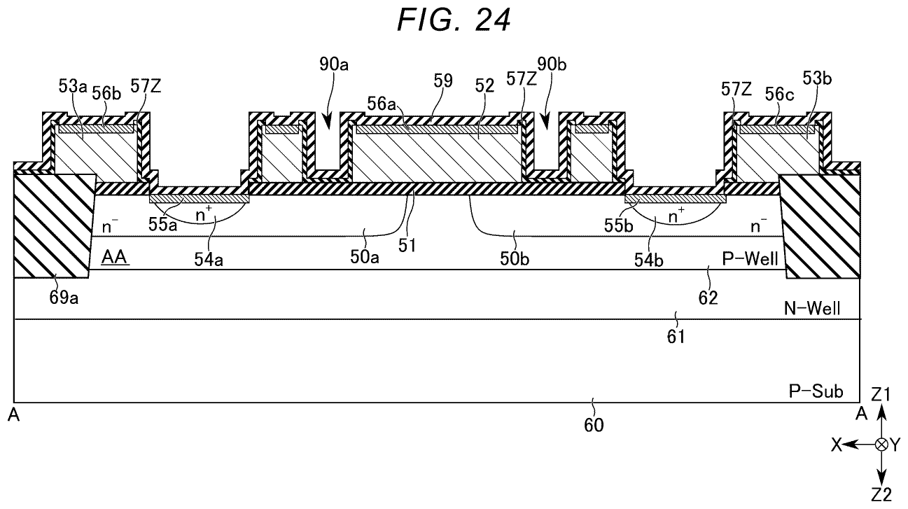

FIGS. 23 and 24 are cross-sectional process diagrams showing a plurality of manufacturing processes in a manufacturing method of the memory device 1 according to the present embodiment. FIGS. 23 and 24 respectively show the manufacturing processes of the high breakdown voltage transistor HTR in the semiconductor chip 2000 including the peripheral circuit PERI. FIGS. 23 and 24 show cross sections of the high breakdown voltage transistor HTR in the channel length direction.

In the present embodiment, similar to FIGS. 18 and 19 described above, the mask layer 93 having a predetermined pattern is formed on the gate electrodes 52 and 53. A portion of the gate insulation layer 51 on the source/drain layer 50 is removed by etching based on the pattern of the mask layer 93. During the etching, the portion 515 in the slit 90 is covered with the mask layer 93. For this reason, the portion 515 is not etched. Accordingly, the portion 515 maintains the film thickness tk1 from the time of forming the gate insulation layer 51.

As shown in FIG. 23, after the diffusion layer 54 is formed in the source/drain layer 50, the block layer 57Z is formed on the gate electrodes 52 and 53 and the diffusion layer 54 by film deposition technology (e.g., CVD).

In a region where silicide is to be formed, the opening OP2 is formed in the block layer 57Z by photolithography and etching. In the slit 90, the block layer 57Z is provided on the upper surface of the gate insulation layer 51.

The conductive layers 55 and 56 are formed on the diffusion layer 54 and the gate electrodes 52 and 53 by a salicide process (self-aligned silicidation).

The block layer 57Z prevents silicidation of materials including silicon. Accordingly, in the gate electrodes 52 and 53 and the diffusion layer 54, the conductive layers 55 and 56 are not formed in the portion covered with the block layer 57Z.

As shown in FIG. 24, the liner layer 59 is formed on the conductive layers 55 and 56 and on the block layer 57Z, covering the gate electrodes 52 and 53. In the slit 90, the block layer 57Z is provided between the liner layer 59 and the portion 515 of the gate insulation layer 51.

Then, similar to described above, the contacts CP0, CP1, and CP4, the conductive layers 82a, 82b, and 82c, the plugs VP, the conductive layers 83a, 83b, and 83c and corresponding insulating layers are sequentially formed. The semiconductor chip 2000 including the formed high breakdown voltage transistor HTR is bonded to the semiconductor chip 1000.

By the manufacturing process described above, the memory device 1 according to the present embodiment is completed.

### (c) Summary

In the memory device 1 according to the present embodiment, the high breakdown voltage transistor HTR includes the block layer 57Z (insulating layer) for preventing the silicidation of certain materials. The block layer 57Z is formed after the process of forming the opening in the gate insulation layer 51.

During the process of forming the opening in the gate insulation layer 51, the gate insulation layer 51 at the position of the slit 90 between the gate electrodes 52 and 53 is covered with the mask layer 93.

Accordingly, even when the block layer 57Z between the gate insulation layer 51 and the liner layer 59 is formed after the opening in the gate insulation layer 51, the memory device 1 according to the present embodiment can prevent the portion 515 of the gate insulation layer 51 at the position of the slit 90 between the gate electrodes 52 and 53 from being thinned by etching during the formation of the opening in the gate insulation layer 51.

Accordingly, in the memory device 1 according to the present embodiment, the high breakdown voltage transistor HTR can keep a relatively large distance between the liner layer 59 (including silicon nitride) and the semiconductor substrate 60.

Furthermore, in the present embodiment, the block layer 57Z is provided between the liner layer 59 and the gate insulation layer 51. As a result, the distance between the liner layer 59 and the semiconductor substrate 60 further increases.

As a result, in the memory device 1 according to the present embodiment, the high breakdown voltage transistor HTR can prevent the deterioration of BT characteristics of the high breakdown voltage transistor that might otherwise be caused by the charge trapping in the liner layer 59.

As described above, the memory device 1 and the semiconductor device HTR according to the third embodiment can improve the device reliability.

### (4) Others

In embodiments described above, the high breakdown voltage transistor HTR has a structure including one main gate electrode 52 and two ring-shaped gate electrodes 53. Alternatively, the high breakdown voltage transistor HTR according to an embodiment may have a structure that includes the main gate electrode 52 and just one ring-shaped gate electrode 53.

In an embodiment, the memory device 1 is a NAND flash memory. In other embodiments, the memory device 1 may be a memory device other than a NAND flash memory that includes a transistor HTR having a structure as described above for other embodiments. For example, the memory device 1 according to additional embodiments may be a phase change memory, a resistance change type memory, a magnetoresistance effect memory, or a ferroelectric memory.

A transistor HTR having the structure described above may be applied to a device other than a memory device. For example, the transistor HTR may be incorporated in a processor, an image sensor, a power device, or an application specific integrated circuit (ASIC).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device, comprising:
a memory cell that stores data; and
a first transistor including:
a first source/drain layer in a semiconductor substrate,
a second source/drain layer in the semiconductor substrate and spaced from the first source/drain layer in a first direction parallel to a surface of the semiconductor substrate,
a first gate insulation layer on the semiconductor substrate,
a first gate electrode above a channel region between the first and second source/drain layers via the first gate insulation layer,
a second gate electrode above the first source/drain layer via the first gate insulation layer, the second gate electrode being adjacent to the first gate electrode across a first slit and including a first opening reaching the first source/drain layer, and
a first insulating layer in the first slit, the first insulating layer comprising silicon nitride, wherein
the first gate insulation layer includes:
a first portion between the first gate electrode and the semiconductor substrate in a second direction orthogonal to the surface of the semiconductor substrate; and
a second portion aligned with the first slit along the second direction, and
the first and second portions of the first gate insulation layer have a same film thickness in the second direction.

2. The memory device according to claim 1, wherein a level in the second direction of an upper surface of the second portion is equal to a level in the second direction of an upper surface of the first portion.

3. The memory device according to claim 1, wherein a level in the second direction of a lower surface of the first insulating layer is above a level in the second direction of a lower surface of the first gate electrode.

4. The memory device according to claim 1, wherein a level in the second direction of a lower surface of the first insulating layer is equal to a level in the second direction of a lower surface of the first gate electrode.

5. The memory device according to claim 1, wherein
the first transistor further includes:
a second insulating layer on the first gate electrode, the second gate electrode, and the first gate insulation layer, and
in the first slit, the second insulating layer is between the first insulating layer and the first gate insulation layer.

6. The memory device according to claim 5, wherein
in the first slit, the second insulating layer is on a sidewall surface of the first gate electrode and a sidewall surface of the second gate electrode, and
in the first slit, the first insulating layer is between the second insulating layer on the sidewall surface of the first gate electrode and the second insulating layer on the sidewall surface of the second gate electrode in the first direction.

7. The memory device according to claim 5, wherein
in the first slit, the second insulating layer is on a sidewall surface of the first gate electrode and a sidewall surface of the second gate electrode, and
a total width dimension of the first slit in the first direction is greater than the sum of a film thickness of the second insulating layer on the sidewall surface of the first gate electrode in the first direction and a film thickness of the second insulating layer on the sidewall surface of the second gate electrode in the first direction.

8. The memory device according to claim 5, wherein
the second insulating layer is the same material as the first gate insulation layer, and
the second insulating layer is a different material than the first insulating layer.

9. The memory device according to claim 1, further comprising:
a third insulating layer on the semiconductor substrate and covering the first and second gate electrodes; and
a first contact in the third insulating layer and electrically connected to the first source/drain layer through the first opening, wherein
a portion of the third insulating layer is in the first slit.

10. The memory device according to claim 1, wherein
the first transistor further includes:
a third gate electrode above the second source/drain layer via the first gate insulation layer, the third gate electrode being adjacent to the first gate electrode across a second slit, and including a second opening reaching the second source/drain layer,
the first gate electrode is between the second gate electrode and the third gate electrode in the first direction,
the first gate insulation layer includes a third portion aligned with the second slit along the second direction, and
the third portion of the first gate insulation layer has a film thickness in the second direction that is equal to the first and second portions of the firs gate insulation layer.

11. A semiconductor device, comprising:
a first source/drain layer in a semiconductor substrate;
a second source/drain layer in the semiconductor substrate and spaced from the first source/drain layer in a first direction parallel to a surface of the semiconductor substrate;
a first gate insulation layer on the semiconductor substrate;
a first gate electrode above a channel region between the first and second source/drain layers via the first gate insulation layer;
a second gate electrode above the first source/drain layer via the first gate insulation layer, the second gate electrode being adjacent to the first gate electrode across a first slit and including a first opening reaching the first source/drain layer; and
a first insulating layer in the first slit, the first insulating layer comprising silicon nitride, wherein
the first gate insulation layer includes:
a first portion between the first gate electrode and the semiconductor substrate in a second direction orthogonal to the surface of the semiconductor substrate; and
a second portion aligned with the first slit along the second direction, and
the first and second portions of the first gate insulation layer have a same film thickness in the second direction.

12. The semiconductor device according to claim 11, wherein a level in the second direction of an upper surface of the second portion is equal to a level in the second direction of an upper surface of the first portion.

13. The semiconductor device according to claim 11, wherein a level in the second direction of a lower surface of the first insulating layer is above a level in the second direction of a lower surface of the first gate electrode.

14. The semiconductor device according to claim 11, wherein a level in the second direction of a lower surface of the first insulating layer is equal to a level in the second direction of a lower surface of the first gate electrode.

15. The semiconductor device according to claim 11, the first transistor further includes:
a second insulating layer on the first gate electrode, the second gate electrode, and the first gate insulation layer, and
in the first slit, the second insulating layer is between the first insulating layer and the first gate insulation layer.

16. The semiconductor device according to claim 15, in the first slit, the second insulating layer is on a sidewall surface of the first gate electrode and a sidewall surface of the second gate electrode, and
in the first slit, the first insulating layer is between the second insulating layer on the sidewall surface of the first gate electrode and the second insulating layer on the sidewall surface of the second gate electrode in the first direction.

17. The semiconductor device according to claim 15, wherein
in the first slit, the second insulating layer is on a sidewall surface of the first gate electrode and a sidewall surface of the second gate electrode, and
a total width dimension of the first slit in the first direction is greater than the sum of a film thickness of the second insulating layer on the sidewall surface of the first gate electrode in the first direction and a film thickness of the second insulating layer on the sidewall surface of the second gate electrode in the first direction.

18. The semiconductor device according to claim 15, wherein
the second insulating layer is the same material as the first gate insulation layer, and
the second insulating layer is a different material than the first insulating layer.

19. The semiconductor device according to claim 11, further comprising:
a third insulating layer on the semiconductor substrate and covering the first and second gate electrodes; and
a first contact in the third insulating layer and electrically connected to the first source/drain layer through the first opening, wherein
a portion of the third insulating layer is in the first slit.

20. The semiconductor device according to claim 11, wherein
the first transistor further includes:
a third gate electrode above the second source/drain layer via the first gate insulation layer, the third gate electrode being adjacent to the first gate electrode across a second slit, and including a second opening reaching the second source/drain layer,
the first gate electrode is between the second gate electrode and the third gate electrode in the first direction,
the first gate insulation layer includes a third portion aligned with the second slit along the second direction, and
the third portion of the first gate insulation layer has a film thickness in the second direction that is equal to the first and second portions of the firs gate insulation layer.
